(19) United States
(12) Patent Application Publication
(10) Pub. No.: US 2022/0081227 A1
(43) Pub. Date: Mar. 17, 2022

(54) DEVICES, SYSTEMS, AND METHODS FOR CONTROLLING FLOATATION OF A SUBSTRATE

(71) Applicant: Kateeva, Inc., Newark, CA (US)

(72) Inventor: Digby PUN, Newark, CA (US)

(73) Assignee: KATEEVA, INC., Newark, CA (US)

(21) Appl. No.: 17/309,801

(22) PCT Filed: Dec. 13, 2019
(86) PCT No.: PCT/US2019/066236

§ 371 Date: Jun. 18, 2021

Related U.S. Application Data
(60) Provisional application No. 62/784,216, filed on Dec. 21, 2018.

(51) Int. Cl. B65G 49/06; B05C 13/02; B05B 13/02; B65H 5/22; H01L 51/00; H01L 51/56

(52) U.S. Cl. CPC B65G 49/065; B05C 13/02; B05B 13/02; B65H 5/228; B65H 2801/61; H01L 51/56; B65G 2249/00; B65H 2406/112; B65H 2406/1132; H01L 51/0005

(57) ABSTRACT

A system comprises a floatation table comprising a plurality of ports to flow gas sufficient to produce a gas bearing to float a substrate over the floatation table; a fluidic network coupled to supply gas to the plurality of ports of the floatation table; and a controller configured to control the fluidic network to independently control flows of gas through ports of the plurality of ports disposed in each of a first zone, a second zone, and a third zone of the floatation table. The first, second, and third zones are defined by sections of the floatation table extending parallel to a direction the substrate is conveyed along the floatation table. The first zone is defined by a central section of the floatation table disposed between two sections defining the second zone, and the first and second zones are disposed between two sections defining the third zone.

### CROSS-REFERENCE TO RELATED APPLICATIONS

This application claims priority to U.S. Provisional Application No. 62/784,216, filed Dec. 21, 2018, entitled “Devices, Systems, and Methods for Controlling Floatation of a Substrate,” which is incorporated by reference herein in its entirety.

### TECHNICAL FIELD

The present disclosure generally relates to devices, systems, and methods for supporting a substrate via floatation, such as, for example, during processing of the substrate. More specifically, the present disclosure relates to controlling floatation of the substrate during processing of the substrate for the manufacture of electronic display devices.

### INTRODUCTION

Electronic devices, such as optoelectronic devices, can be fabricated using various thin-film deposition and processing techniques in which one or more layers of materials are deposited onto a substrate, which can be a sacrificial substrate or be part of a final device. Examples of such devices include, but are not limited to, microchips, printed circuit boards, solar cells, electronic displays (such as liquid crystal displays, organic light emitting diode displays, and quantum dot electroluminescent displays), or other devices. Applications for electronic display devices also can include general illumination, use as a backlight illumination source, or use as a pixel light source. One class of optoelectronic devices includes organic light emitting diode (OLED) devices, which can generate light using electroluminescent emissive organic materials such as small molecules, polymers, fluorescent, or phosphorescent materials.

The manufacture of organic light emitting devices (OLEDs) generally involves depositing one or more organic materials on a substrate to form a stack of thin films, and coupling the top and bottom of the stack of thin films to electrodes. Various techniques can be used to form the stack of thin films. In a thermal evaporation technique, organic material may be vaporized in a relative vacuum environment and subsequently condensed on the substrate. Another technique for forming the stack of thin films involves dissolution of the organic material into a solvent, coating the substrate with the resulting solution, and subsequent removal of the solvent. An ink jet or thermal jet printing system may be used for deposition of organic material dissolved in a solvent.

Because materials used in electronic device manufacturing, such as, for example, organic materials used in OLED devices, also may be highly sensitive to exposure to various ambient materials, such as oxygen, ozone, water and/or other vapor (e.g., solvent vapor), the entire system for substrate printing may be housed in an enclosure, in which a low-particle, non-reactive atmosphere may be maintained using one or more inert gases or noble gases and a gas circulation and filtration system that removes particles generated by the printing system from the interior of the enclosure.

Particulate contamination, as well as contact from other system components with the substrate or the layers deposited on the substrate during processing, can also affect the quality of various electronic devices, including OLED devices. Various methods may be used to support a substrate during the fabrication process of an optoelectronic device. For example, the substrate may be supported by a mechanical platform (sometimes referred to as a table or a chuck) that employs vacuum or mechanical clamping to hold the substrate in place during processing. Lift pins may be used to support center regions of the substrate, for example, to raise or lower the substrate with respect to the chuck to facilitate loading and unloading. In the case of vacuum chucks, vacuum holes or grooves in portions of the chuck over which center regions of the substrates are positioned may be used to hold the substrate down in place. Such holes or grooves may cause non-uniformities (or “mura”), for example, in the organic material layers deposited onto the substrate during an OLED device manufacturing process. In addition, physical contact with the substrate at active regions on which organic materials are deposited may also cause the mura phenomenon. In general, the mura phenomenon can occur in thin film deposition processes other than OLED device manufacturing processes. The severity of the mura phenomenon may depend on properties of the material deposited on a substrate, such as dielectric, volatility, and fluidity properties, for example. Thus, the disclosed devices, systems, and methods may also be applicable to other thin film deposition processes.

Generally, if active regions of a substrate are not supported continuously and uniformly (e.g., with a uniform application of force along the surface of the substrate underneath an active region of the substrate) during or after the material deposition (e.g., printing) process, non-uniformities or visible defects may exist in the organic material deposited onto the substrate. Various specialized uniform support techniques can be used to achieve uniform, substantially defect-free coatings. For example, non-uniform or physical support may be provided at non-active regions of the substrate, such as the peripheral areas of the substrate that will not form part of the active electronics and emissive portions of the display (e.g., peripheral regions where organic material is not deposited in OLED devices). Additionally, non-contact supporting of the substrate may be used to support the substrate during printing, conveyance, and/or thermal treatment processes. Such non-contact supporting can be achieved using a floatation system that uses gas bearings to float (lift) the substrate above the surface of a floatation table. In an implementation of a floatation table, a combination of pressure ports emitting pressurized gas and suction ports drawing in gas (e.g., vacuum) are used to create a tightly controlled fluidic spring gas bearing. The pressurized gas outlet ports provide the lubricity and non-contacting floatation support for the substrate, while the suction ports support the counter-force necessary to strictly control the height at which the relatively light-weight substrate floats. Such floatation systems can use various gases, including but not limited to, for example, nitrogen or other inert gases, noble gases, air, or a combination thereof.

While floatation system designs allow for controlled vertical (e.g., z-direction of an x-y-z Cartesian coordinate system, wherein the substrate lies generally in an x-y plane) floatation of a substrate over the surface of the floatation table, controlling the fly height of the substrate (i.e., the height of the substrate over the surface of the floatation table) in a robust manner remains challenging. When pressurized gas is supplied in a space between the surface of the floatation table and the substrate, the gas can accumulate and become trapped in one or more regions (such as, for example, a central region) under of the substrate. Such accumulation may particularly occur when no or an insufficient escape path (e.g., vacuum port or opening, or dedicated escape port or opening) is provided on the floatation table. As the gas accumulates, the pressure of the trapped gas in the one or more regions under the substrate becomes higher than the pressure of the gas in other regions of the space under the substrate (e.g., non-central regions and/or edge regions) under the substrate. The high pressure associated with the gas trapped in the one or more regions of the space under the substrate can create an unstable and/or unpredictable pathway for the gas to exit or escape the space. Gas may exit or escape the central region of the space toward any peripheral region in a random direction, following whichever path has the least resistance. That is, the escape path may be random. When the gas escapes along the escape path, the fly height of the portions of substrate along the escape path increases. Other portions of the substrate, such as the corner or edge portions, which are located at places opposite the escape path may experience a reduction in the fly height due to the loss of the gas escaping along the escape path. The reduction in the fly height at the edge or corner portions of the substrate may lead to collision or other contact of the substrate with other objects on the surface of the floatation table. Such contact may cause scratches or other damage to the substrate, which in turn can lead to mura phenomenon and generation particulate matter that may contaminate the surface of the substrate. Therefore, there remains a need to have systems and methods that can control the pressure of the gas in the space between the surface of the flotation table and the substrate, and more robustly control the floatation of the substrate.

Such nonuniform pressures under the substrate also can occur in floatation tables or regions of floatation tables that use pressurized gas to support the substrate without suction gas creating a counterforce to the pressurized gas to produce a fluidic spring that tightly controls the fly height of the substrate. Such pressurized gas support, without the use of suction ports, generally are used in infeed and outfeed regions to a substrate processing region because such infeed and outfeed regions to not require as precise a control over the fly height of the substrate.

### SUMMARY

According to an exemplary embodiment, the present disclosure contemplates a system, comprising a floatation table comprising a plurality of ports to flow gas sufficient to produce a gas bearing to float a substrate over the floatation table; and a fluidic network coupled to supply gas to the plurality of ports of the floatation table. The system further comprises a controller configured to control the fluidic network to independently control flows of gas through ports of the plurality of ports disposed in each of a first zone, a second zone, and a third zone of the floatation table, wherein the first, second, and third zones are defined by sections of the floatation table extending parallel to a direction the substrate is conveyed along the floatation table, the first zone is defined by a central section of the floatation table disposed between two sections defining the second zone, and the first and second zones are disposed between two sections defining the third zone.

According to another exemplary embodiment, a method comprises flowing gas from a plurality of ports of a floatation table to establish a gas bearing under a surface of a substrate, the gas bearing being sufficient to float a substrate the floatation table as the substrate is conveyed along the floatation table; and independently controlling flows of gas through ports of the plurality of ports disposed in each of a first zone, a second zone, and a third zone of the floatation table. The first, second, and third zones are defined by sections of the floatation table extending parallel to a direction the substrate is conveyed along the floatation table, wherein the first zone is defined by a central section of the floatation table disposed between two sections defining the second zone, and the first and second zones are disposed between two sections defining the third zone.

In yet another exemplary embodiment, a method includes flowing gas from a plurality of ports of a floatation table to establish a gas bearing under a surface of a substrate, the gas bearing being sufficient to float a substrate the floatation table as the substrate is conveyed along the floatation table. Flowing the gas comprises flowing a first gas at a first flow rate and a first pressure through a first plurality of ports of a floatation table, and flowing a second gas at a second flow rate and a second pressure through a second plurality of ports of the floatation table. The second plurality of ports are located under two opposite lateral edge regions of the substrate, the first plurality of ports are located under a region of the substrate between the two opposite lateral edge regions, and at least one of the second flow rate and the second pressure is greater than at least one of the first flow rate and the first pressure.

In another exemplary embodiment, the present disclosure contemplates a system comprising a floatation table comprising a plurality of ports to flow gas sufficient to produce a gas bearing to float a substrate over the floatation table, a fluidic network coupled to supply gas to the plurality of ports of the floatation table, and a controller operably coupled to the fluidic network. The controller is configured to control a flow of a first gas from a first plurality of the ports at a first pressure and a first flow rate, and control a flow of a second gas from a second plurality of the ports at a second pressure and a second flow rate, at least one of the second pressure and the second flow rate being greater than at least one of the first pressure and the first flow rate. The first plurality of ports are located in a central section of the floatation table and disposed between two sections of the floatation table in which the second plurality of the ports are located.

In another exemplary embodiment, the present disclosure contemplates a method of processing a comprising supporting the substrate over a floatation table using a gas bearing produced by the floatation table. While supporting the substrate, the method also includes conveying the substrate between a first region of the floatation table and a second region of the floatation table. The method also comprises controlling gas flow in differing zones of the floatation table so as to allow gas to escape in a substantially uniform manner from under the substrate while the substrate is in the first region, and controlling a gas flow from the floatation table to produce a fluidic spring to control a fly height of the substrate while the substrate is in the second region.

Additional objects, features, and/or other advantages will be set forth in part in the description which follows, and in part will be obvious from the description, or may be learned by practice of the present disclosure and/or claims. At least some of these objects and advantages may be realized and attained by the elements and combinations particularly pointed out in the appended claims.

Both the foregoing general description and the following detailed description are exemplary and explanatory only and are not restrictive of the claims; rather the claims should be entitled to their full breadth of scope, including equivalents.

### BRIEF DESCRIPTION OF THE DRAWINGS

The present disclosure can be understood from the following detailed description, either alone or together with the accompanying drawings. The drawings are included to provide a further understanding of the present disclosure, and are incorporated in and constitute a part of this specification. The drawings illustrate one or more exemplary embodiments of the present teachings and together with the description explain certain principles and operation.

FIG. 1 schematically illustrates a partial, top, perspective view of various printing system components for electronic device manufacture in accordance with an exemplary embodiment of the present disclosure.

FIG. 2 schematically illustrates a partial side, cross-sectional view of a floatation table supporting a substrate to schematically depict issues associated with trapped gas.

FIG. 3 schematically illustrates a partial side, cross-sectional view of an exemplary embodiment of a floatation table supporting a substrate in accordance with the present disclosure.

FIG. 4 schematically illustrates a partial side, cross-sectional view of another exemplary embodiment of a floatation table supporting a substrate in accordance with the present disclosure.

FIG. 5 schematically illustrates a partial side, cross-sectional view of yet another exemplary embodiment of a floatation table supporting a substrate in accordance with the present disclosure.

FIG. 6 schematically illustrates a partial top, plan view of a simplified floatation table with an arrangement of edge control ports at the edges of floatation table, in accordance with an exemplary embodiment of the present disclosure.

FIG. 7 schematically illustrates a partial top, plan view of a simplified floatation table with another arrangement of edge control ports at the edges of floatation table, in accordance with another exemplary embodiment of the present disclosure.

FIG. 8 schematically illustrates a partial top, plan view of a simplified floatation table with another arrangement of edge control ports at the edges of floatation table, in accordance with another exemplary embodiment of the present disclosure.

FIG. 9 is a flowchart illustrating exemplary steps of a method for supporting a substrate in accordance with the present disclosure.

FIG. 10 is a flowchart illustrating exemplary steps of another method for supporting a substrate in accordance with the present disclosure.

FIG. 11 schematically illustrates a floatation table structure that includes three different longitudinally extending sections of gas flow ports, wherein the gas flow from the ports of each section is independently controllable in accordance with an exemplary embodiment of the present disclosure.

FIG. 12 schematically illustrates a system for controlling the gas flows supplied to the different sections of ports of the floatation table of FIG. 11, in accordance with an exemplary embodiment of the present disclosure.

### DETAILED DESCRIPTION OF EXEMPLARY EMBODIMENTS

This description and the accompanying drawings that illustrate aspects and embodiments should not be taken as limiting. The claims define the scope of protection including equivalents. Various mechanical, compositional, structural, electrical, and operational changes may be made without departing from the scope of this description and the claims. In some instances, well-known circuits, structures, and techniques have not been shown or described in detail in order not to obscure the invention. In various embodiments, like numbers in two or more figures represent the same or similar elements.

Further, this description's terminology is not intended to limit the scope of the claims. For example, spatially relative terms—such as “beneath,” “below,” “lower,” “above,” “upper,” “proximal,” “distal,” “x-direction,” “y-direction,” “z-direction,” and the like—may be used to describe one element's or feature's relationship to another element or feature as illustrated in the figures. These spatially relative terms are intended to encompass different directions (e.g., in a Cartesian coordinate system), positions (i.e., locations) and orientations (i.e., rotational placements) of a device in use or operation in addition to the position and orientation shown in the figures. For example, if a device in the figures is turned over, elements described as “below” or “beneath” other elements or features would then be “above” or “over” the other elements or features. Thus, the exemplary term “below” can encompass both positions and orientations of above and below. A device may be otherwise oriented (rotated 90 degrees or at other orientations) and the spatially relative descriptors used herein interpreted accordingly. Likewise, descriptions of movement along and around various axes include various special device positions and orientations. In addition, the singular forms “a,” “an,” and “the” are intended to include the plural forms as well, unless the context indicates otherwise. And, the terms “comprises,” “comprising,” “includes,” and the like specify the presence of stated features, steps, operations, elements, and/or components but do not preclude the presence or addition of one or more other features, steps, operations, elements, components, and/or groups. Components described as coupled may be electrically or mechanically directly coupled, or they may be indirectly coupled via one or more intermediate components. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

Elements and their associated aspects that are described in detail with reference to one embodiment may, whenever practical, be included in other embodiments in which they are not specifically shown or described. For example, if an element is described in detail with reference to one embodiment and is not described with reference to a second embodiment, the element may nevertheless be claimed as included in the second embodiment.

Exemplary embodiments described herein include systems, methods, and devices for supporting a substrate during fabrication of any of a variety of electronic devices, such as, for example, OLED display devices. Exemplary disclosed systems, methods, and devices may enable selective zones of gas flow to achieve desired and predictable gas flow paths. Selectively controlling gas flow supplied to different regions of a substrate may provide substantially uniform pressure across a surface of the substrate to which gas is flowed to float the substrate more stably, thereby reducing risk of collision and damage of the substrate. For example, with the disclosed systems, methods, and devices, gas flow from different zones of a floatation table may be independently controlled. The different zones of the floatation table may include different ports for providing gas flows. Ports located at different positions relative to the substrate may be selected to provide gas flows that achieve different functions, such as floating the substrate, controlling fly heights of different regions of the substrate, conveying the substrate, etc. By controlling the flow (e.g., pressures and/or flow rates) of the gas supplied to different regions of the substrate, the substrate can be maintained in a desired shape and fly height profile, and thereby reducing a risk of unstable floatation and damage to the substrate. That is, the gas flows at different regions of the substrate may be separately controlled via controlling the flow (e.g., pressures and/or flow rates) of the gas supplied from different ports located on the floatation table corresponding to different regions of the substrate.

In some embodiments, exemplary disclosed devices, systems, and methods may include a floatation table having different gas supply zones (each zone having one or more ports) for providing different gas flows to different regions of a substrate, thereby establishing desired gas flow paths for the gas to escape the space between the substrate and the floatation table. The desired gas flow paths in turn establish a substantially uniform gas pressure under the substrate, thereby maintaining the substrate in a desired shape (substantially flat surface profile) while the substrate is floated by the gas flows. For example, in some embodiments, the floatation table may include a first plurality of ports to supply gas to float the substrate over the surface of the floatation table, and a second plurality of ports to supply gas at a higher pressure and/or flow rate at a particular region of the substrate. In some embodiments, the floatation table may include ports used at the lateral edges of the substrate to provide a fly height and overall gas flow distribution in the space between the substrate and the floatation table that provides an escape path for the gas to avoid accumulation of gas and consequent bowing of the substrate in a central region of the substrate. Such ports are referred to herein as “edge control ports”. The edge control ports may be located on the floatation table corresponding to lateral edges of the substrate to provide sufficient forces (generated by the gas flows provided from the edge control ports) to control the fly heights of the substrate, thereby preventing uneven pressure buildup under the surface of the substrate facing away from the floatation table while the substrate is floated over the surface of the floatation table.

In an exemplary embodiment, the edge control ports may be distributed in an infeed region and an outfeed region of the floatation table where no escape ports or paths (e.g., no suction ports) are provided for the gas trapped at the more central regions of a substrate to escape the space between the substrate and the floatation table. Providing the edge control ports at suitable locations on the floatation table (e.g., at the lateral edges of the floatation table) can produce a gas flow profile across the substrate that permits an escape path for the gas bearing that is more predictable, in turn causing the fly height and pressure of the gas under the substrate to be more controllable and stable. For discussion purposes, the disclosed systems are referred to as systems for fabricating OLED devices. However, one of ordinary skill in the art would understand that the disclosed systems may be used for other purposes, including fabrication of other devices (such as other electronic devices using substrate deposition techniques), processing of other materials (other than the organic material disclosed herein), or processing of substrates for other purposes (e.g., cleaning, thermal treating, etc.).

Gas that is supplied to different ports, nozzles, openings, or the like in some instances herein may be referred to as a first gas, a second gas, a third gas, etc. to facilitate distinction between gas supplied to one set of ports, nozzles, or the like versus another set. It is contemplated that the supplied gasses when so referenced may be the same as, or one or more may differ, from each other.

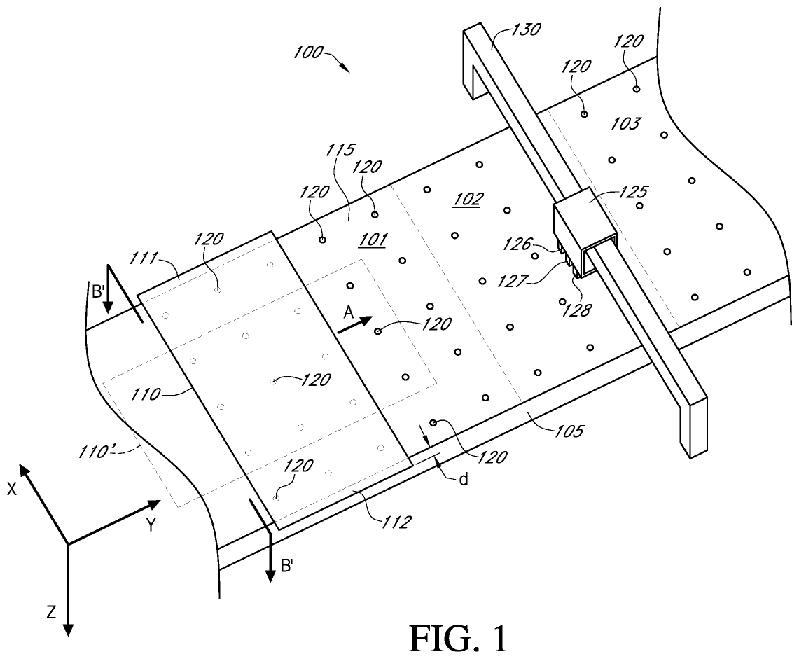

FIG. 1 schematically illustrates an exemplary system 100 that may be used for depositing a material on a substrate during a manufacturing process, such as the manufacture of various electronic devices, including but not limited to OLED devices. Although not shown in FIG. 1, those having ordinary skill in the art would appreciate that system 100 can include various other components and may be a subsystem that is part of a larger overall fabrication system. By way of example, system 100 may include or be operably coupled to a thermal treatment system or section having one or more thermal treatment devices (e.g., heaters, coolers, UV treatment devices, etc.) for treating materials before and/or after the materials are deposited onto the substrates using various technologies. Similarly, system 100 may include or be operably coupled to one or more cooling sections or zones including one or more cooling devices for reducing the temperature of substrates. System 100 may include or be operatively coupled to one or more holding sections or zones having structures (such as stacked shelves) configured to hold substrates before or after the materials are deposited onto the substrates.

In some embodiments, system 100 is in an enclosure (not shown). The enclosure may be hermetically sealed. An environment in the enclosure may be controlled and maintained as a low-particle and/or non-reactive environment. For example, system 100 can include a gas circulation and filtration system configured to circulate and filter the gas, which can be an inert gas, in the enclosure. The inert gas may be non-reactive with the material (such as an organic material) deposited on the substrate. The gas may be nitrogen or other inert gases, noble gases, air, or a combination thereof. The gas circulation and filtration system may include at least a portion disposed in the enclosure, and at least another portion disposed outside of the enclosure. The gas circulation and filtration system may remove particles, water vapor, oxygen, and ozone content from the environment in the enclosure, such that the particles, water vapor, oxygen, and ozone content, if present, may be maintained below specified limits, such as 100 ppm, 50 ppm, 10 ppm, 1 ppm, 0.1 ppm, etc. A gas purification system for removing one or more reactive species, such as ozone, water vapor, and/or solvent vapor, also may be operably coupled to the enclosure. Non-limiting examples of such systems for manufacture of electronic device components, including for printing of displays, are disclosed in U.S. Patent Application Publication Nos. US 2014/0311405 A1, US 2017/0028731 A1, and US 2018/0014411 A1, and U.S. Pat. No. 9,505,245, the entirety of each of which is incorporated by reference herein.

System 100 may include a substrate support apparatus 105 for supporting and/or conveying (e.g., translating and/or rotating) a substrate 110. In various exemplary embodiments, the substrate support apparatus is a floatation table 105. Floatation table 105 may be configured to support substrate 110 in a non-contact manner by establishing a gas bearing to float substrate 110 at any suitable stage during processing of substrate 110 in the system 100.

Floatation table 105 may be a single-piece plate having a predetermined thickness, as shown in FIG. 1. Floatation table 105 may include different regions along which a substrate is conveyed during fabrication of an electronic device. For example, floatation table 105 may include an infeed region 101, a printing region 102, and an outfeed region 103. Infeed region 101 may be located upstream of printing region 102 in a conveyance direction A of substrate 110 (although in printing region 102, substrate 110 may be moved back and forth in both directions). Outfeed region 103 may be located downstream of printing region 102 in the conveyance direction A of substrate 110. Additional regions of the floatation table also may be included, such as a treatment region, a holding region, etc. The platform of floatation table 105 may be made of aluminum, ceramic, steel, a combination thereof, or any other suitable materials. Floatation table 105 may be supported on a supporting frame or structure for example relative to a ground surface, which is not shown in FIG. 1.

As shown in FIG. 1, floatation table 105 includes a plurality of ports 120. The term “port” refers to an opening provided in floatation table 105, a port of a nozzle that is disposed within the opening of floatation table 105, or a combination of the opening and the port of the nozzle disposed within the opening. Ports 120 may extend into a thickness of floatation table 105 and open at a top support surface 115 of floatation table 105. In some embodiments, ports 120 may include through holes in floatation table 105, which may extend from top support surface 115 to a bottom surface of floatation table 105 opposite surface 115. Ports 120 may have the same or different sizes. In some embodiments, a first plurality of ports 120 (e.g., openings 120) may have a first size (e.g., a first diameter), and a second plurality of openings 120 (e.g., openings 120) may have a second size (e.g., a second diameter), which may be different from the first size. Ports 120 may have the same or different shapes. In some embodiments, a first plurality of ports 120 may have a first shape, such as circular. A second plurality of ports 120 may have a second shape, such as oval, different from the first shape.

Ports 120 may be arranged to provide various functions. For example, a first plurality of ports 120 (or all of ports 120) may be arranged to flow a gas to form a gas bearing between surface 115 and substrate 110 for floating substrate 110 over surface 115. In some embodiments, the gas supplied to ports 120 may be air, a noble gas, an inert gas, or any other suitable gas or combinations thereof. The first plurality of ports 120 may be configured to direct flows of a gas in a direction that may be substantially normal or perpendicular to surface 115. The gas flowing into or out of the first plurality of ports 120 may form a gas bearing between a lower surface of substrate 110 and surface 115 of floatation table 105. The gas bearing may be sufficient to floatingly support (i.e., float) substrate 110 over or above surface 115 of floatation table 105 at a fly height, which is measured in the z-direction (normal to the surface 115 of the table). The x-y-z Cartesian coordinate system as used herein is reflected in the orientation of the drawings, with it being understood that the x- and y-directions could be switched. The flows of the gas may have a pressure and a flow rate, which may be controlled by a controller and other system components, as discussed below. The controller may control the flow of gas (e.g., at least one of the pressure and the flow rate of the gas) to control the fly height of substrate 110.

Among ports 120 for providing the gas bearing, some ports may be used as pressure ports, through which a pressurized gas is blown from the ports at a positive pressure to the space between substrate 110 and surface 115. The pressure ports may be operably coupled to a pressure source (e.g., a source of pressurized gas). Some ports may be used as suction (e.g., vacuum) ports, through which gas is withdrawn from the space between substrate 110 and surface 115. The suction ports may be operably coupled to a vacuum source (e.g., a vacuum machine or device). For example, in infeed region 101 and outfeed region 103, all the ports for providing the gas bearing may be pressure ports. In some embodiments, there may not be any suction ports provided in infeed region 101 and outfeed region 103. In printing region 102, some ports may be configured as pressure ports and some ports may be configured as suction ports. The pressure ports and the suction ports may be arranged alternately adjacent each other in printing region 102. By providing both pressure and suction in printing region 102, the effective stiffness of the gas bearing is increased (hence the gas bearing in printing region 102 may be also referred to as a fluidic spring), which makes it easier to more accurately control the fly height in printing region 102 as compared to infeed region 101 and outfeed region 103, where only pressure ports are provided.

A second plurality of ports 120 of floatation table 105 may be selected to control (e.g., raise) the fly height of the edge regions of substrate 110. In the embodiment shown in FIG. 1, the substrate is oriented such that it is as wide or wider than the floatation table 105, with lateral edge portions 111 and 112 extending to or overhanging from the edges of floatation table 105. In this embodiment, the second plurality of ports 120 may be located near edges (e.g., lateral edges parallel to a travel direction A of substrate 110, as shown in FIG. 1) of surface 115 to provide control of the fly height of edge regions of substrate 110 (i.e., “edge control”). It is understood, however, the second plurality of ports 120 for edge control do not need to be located at edges of floatation table 105. For example, when substrate 110 is oriented such that it is narrower than floatation table 105, as depicted by the dotted line substrate illustrated in FIG. 1, the second plurality of ports 120 for edge control may be those ports located on floatation table 105 are disposed under edge regions of substrate 110.

In some embodiments, the second plurality of ports 120 may be selected from ports 120 shown in FIG. 1. For example, the second plurality of ports 120 may be selected from those ports that are close to the lateral edges of floatation table 105. In this embodiment, certain ports among ports 120 that are located at the edges of floatation table 105 may be used for providing edge control of the fly height of substrate 110, while other ports among ports 120 may be used for providing the gas bearing to float substrate 110. In some embodiments, all of ports 120 shown in FIG. 1 may be used only for providing the gas bearing, and floatation table 105 may include additional ports (not shown in FIG. 1) dedicated to providing edge control of the fly height of substrate 110, as discussed below.

In some embodiments, a third plurality of ports 120 may be used as parts of a conveyance system for conveying substrate 110 along floatation table 105. Alternatively, additional third plurality of ports may be included in floatation table 105 to provide conveyance of substrate 110 along floatation table 105. The gas flowing out of the third plurality of ports may convey substrate 110 along surface 115, including translating and/or rotating (around the z-axis) substrate 110.

In some embodiments, ports 120 may be supplied with the same gas at the same pressure and same flow rate. In some embodiments, ports 120 may be supplied with the same gas at different pressures and/or different flow rates. In some embodiments, different ports 120 or different groups of ports 120 may be supplied with different gases. The different gases may be supplied at the same or different pressure and/or the same or different flow rate. For example, in some embodiments, certain ports of ports 120 may be supplied with a gas at a pressure that is higher than the pressure of the gas supplied to other ports of ports 120. In some embodiments, certain ports 120 may be supplied with a gas at a flow rate that is greater than the flow rate of the gas supplied to other ports of ports 120. In some embodiments, when all of ports 120 are used for providing the gas bearing, all of ports 120 may be supplied with a same gas at a same pressure and/or flow rate. Alternatively, when all of ports 120 are used for providing the gas bearing, some ports 120 may be supplied with the same gas but at a different pressure and/or flow rate than other ports 120. For example, some ports 120 disposed on floatation table 105 at locations corresponding to a central region of substrate 110 may be supplied with a gas at a lower pressure and/or a lower flow rate than other ports 120 disposed at locations corresponding to a non-central region of substrate 110. In some embodiments, when all of ports 120 are used for providing the gas bearing, additional edge control ports may be distributed along the two opposite lateral edges of floatation table 105 to provide edge control of the fly height of substrate 110. Gas supplied to these additional edge control ports at the edges of floatation table 105 may have a different pressure and/or flow rate than the gas supplied to ports 120 for providing the gas bearing. In some embodiments, a different gas may be supplied to the additional edge control ports compared to ports 120.

Referring again to FIG. 1, system 100 includes a printhead assembly 125 located in printing region 102. Printhead assembly 125 may be mounted on a bridge 130, and may be movable along the bridge 130. For discussion purposes, printhead assembly 125 can include an inkjet printing assembly with at least one inkjet printhead to deposit a material (such as an organic material) in a pattern on a surface of substrate 110 using inkjet printing technology. For example, in the embodiment shown in FIG. 1, printhead assembly 125 includes a plurality of printheads 126, 127, and 128. Each of printheads 126, 127, and 128 may be configured to deposit a material, such as an organic material, onto substrate 110 to form one or more layers on substrate 110. Each of printheads 126, 127, and 128 may be an inkjet printhead. The material may be included in an ink. System 100 may include a treatment system having, for example, one or more thermal treatment devices (such as heaters and coolers) to treat the organic material deposited on the substrate to form layers. As discussed above, in various exemplary embodiments, layers formed on substrate 110 may be part of an OLED device.

While FIG. 1 and various exemplary embodiments described herein refer to deposition of materials on a substrate using inkjet printing techniques, those having ordinary skill in the art would understand that such a deposition technique is exemplary only and nonlimiting. Other material deposition techniques, such as, for example, vapor deposition, thermal jet deposition, etc., also may be used with the floatation and conveyance mechanisms of the present disclosure and are considered as within the scope of the present disclosure.

Bridge 130 may be disposed over floatation table 105, for example, across a width of floatation table 105 at a middle section of floatation table 105. For example, bridge 130 may be disposed over printing region 102 of floatation table 105. Printhead assembly 125 is movable along bridge 130 over floatation table 105, e.g., in the x-direction (e.g., width direction of floatation table 105). Substrate 110 may be moved along floatation table 105 (e.g., in conveyance direction A along length direction of floatation table 105) and positioned under bridge 130 and printhead assembly 125. Printhead assembly 125 may deposit the organic material onto an upper surface of substrate 110 to form thin layers that are parts of an OLED device to be fabricated. In some embodiments, printhead assembly 125 may be positioned below substrate 110. For example, printheads may be embedded in or on surface 115 of floatation table 105, and may deposit the organic material onto a lower surface of substrate 110 from below the lower surface of substrate 110.

In some embodiments, printhead assembly 125 is moved in the x-direction and/or y-direction (e.g., substrate conveyance direction) relative to a stationary substrate 110 (e.g., gantry style). For example, printhead assembly 125 may be moved along bridge 130 in the x-direction relative to a stationary substrate 110. In some embodiments, bridge 130 may be mounted on a track and moved along the track, such that printhead assembly 125 may be moved along the y-direction relative to a stationary substrate 110. In some embodiments, printhead assembly 125 may be moved in both the x-direction and the y-direction relative to the stationary substrate 110.

In some embodiments, printhead assembly 125 may be stationary, while substrate 110 may be moved along the x-direction and/or the y-direction on floatation table 105. For example, substrate 110 may be moved in the x-direction relative to the stationary printhead assembly 125. In some embodiments, substrate 110 may be moved in the y-direction relative to the stationary printhead assembly 125. In some embodiments, substrate 110 may be moved in both the x-direction and the y-direction relative to the stationary printhead assembly 125.

In some embodiments, both substrate 110 and the printhead assembly 125 may be moved in at least one of the x-direction and the y-direction relative to one another (e.g., split axis style). For example, substrate 110 may be moved in the x-direction, while the printhead assembly 125 may be moved in the y-direction. In some embodiments, substrate 110 may be moved in the y-direction while printhead assembly 125 may be moved in the x-direction. In some embodiments, substrate 110 may be moved in both the x-direction and the y-direction, and printhead assembly 125 may be moved in both the x-direction and the y-direction relative to the substrate.

In some embodiments, substrate 110 and/or printhead assembly 125 may be moved in the z-direction. For example, substrate 110 may be moved up and down in the z-direction, e.g., through adjusting the force generated by the gas bearing that floatingly supports the substrate, to become closer to and away from printhead assembly 125. In some embodiments, printhead assembly 125 may be further mounted to a Z-axis plate (not shown in FIG. 1) that may be moved up and down in the z-direction on bridge 130 relative to stationary substrate 110. In some embodiments, both substrate 110 and printhead assembly 125 may be moved in the z-direction relative to one another.

Floatation table 105 alone or in conjunction with another mechanical conveyance mechanism may be configured to convey (e.g., translate and/or rotate) substrate 110 to position substrate 110 relative to surface 115 of the floatation table 105, and thus relative to the printhead assembly 125. For example, the substrate 110 can be conveyed along the floatation table 105 from infeed region 101 to printing region 102, and from printing region 102 to outfeed region 103, or back and forth between infeed region 101 and printing region 102, and between printing region 102 and outfeed region 103. While being printed with the organic material at the printing region 102, a portion of the substrate 110 may extend into infeed region 110 and/or outfeed region 103, depending on the size of substrate 110 and the movement of substrate 110 during printing. Substrate 110 also can be conveyed while floating along one or more floatation tables 105 or sections of a floatation table 105 through various sections in system 100, such as a treatment section, a holding section, a cooling section, etc. Alternatively, or additionally, after substrate 110 is conveyed (e.g., translated) to a predetermined location on the floatation table 105, substrate 110 may be gripped mechanically by a gripper system (not shown). One of ordinary skill in the art would appreciate, however, that floatation table 105 can have a variety of formats to achieve different desired conveyance, rotation, and or fly heights as the substrate moves along different regions of a system.

The size of the substrate that can be supported by the disclosed system is not limited. In display manufacturing, substrate sizes are often referred to in terms of generations as Gen n, with n representing a different number and with each generational size roughly corresponding to the overall substrate size that is processed, out of which multiple smaller displays may ultimately be made. Exemplary non-limiting large size substrates of higher generations may be on the order of 1500 mm×1850 mm, or 2200 mm×2500 mm, or 2940 mm×3370 mm, however larger sized substrates and smaller sized substrates of hundreds of millimeters by hundreds of millimeters also are contemplated as within the scope of the present disclosure. The present disclosure embodiments can accommodate any of the generational sizes and is not limited in this regard. However, those having ordinary skill in the art would appreciate that the surface area and drag forces should be considered when determining how any particular generation size can be handled using the techniques described herein according to exemplary embodiments of the present disclosure. Substrates of other sizes may also be processed by the disclosed system.

In some embodiments, as shown in FIG. 1, a width of floatation table 105 may be narrower than or about the same width as a width of substrate 110, such that edge portions 111 and 112 of substrate 110 at the lateral edges align with or hang over the edges of floatation table 105. The width of edge portions 111 and 112 may range from about 10 to about 15 millimeters (mm). The width of the edge portions 111 and 112 overhanging from floatation table 105 may use other values, such as about 0 mm to about 10 mm, or about 15 mm to about 20 mm. In some embodiments, the width of the overhanging edge portions is independent of overall substrate size. Having lateral edge portions of substrate 110 hanging over the edges of floatation table 105 may help control the uniformness of fly height of substrate 110 using the weight of the overhanging lateral edge portions. With the lateral edge portions hanging over the edges of floatation table 105, variance in the fly height of substrate 110 at different portions of substrate 110 may be reduced. More uniform fly height (which means substrate 110 is flatter and its height over the table is more uniform over the entire area of the substrate) can result in better printing effect when organic materials are printed (e.g., deposited) onto the upper surface of substrate 110 at printing region 102.

In the embodiment shown in FIG. 1, floatation table 105 includes a surface 115 (e.g., a continuous surface) with ports distributed therein. Without wishing to be bound by any particular theory, the inventors believe that when gas is supplied to the space between surface 115 and a lower surface of substrate 110 to create a gas bearing using pressurized gas flow out of ports, for example, with no escape ports or suction ports (such as for example in infeed region 101 or in outfeed region 103), the gas tends to accumulate or be trapped at the central region under substrate 110. The accumulation of the gas leads to a build-up of the pressure under certain regions of the substrate, such as at a central region of the substrate. As a result, the substrate 110 can bow in one or more regions. For example, when gas accumulates, and pressure builds up, under a central region of the substrate, the surface of substrate 110 that faces away from floatation table 105 may have a convex shape, with the fly height at the central region of substrate 110 being highest, and the fly height at the edge portions (or regions) of substrate 110 being lowest. Gas accumulated under the substrate 110 tends to escape the space through one or more random escape paths (e.g., whichever path has the least resistance at an instant in time). This leads to a reduction in fly height at one or more random, unpredictable regions of substrate 110. Because the fly height of substrate 110 over the surface of floatation table 105 is typically very small, for example, about 30 microns to 500 microns. In some embodiments, the fly height may be about 250 microns at the central region and about 100 microns at the edges of substrate 110, if the fly heights at the edges are further randomly reduced, the edges of substrate 110 may come into contact with floatation table 105 or other objects on floatation table 105. Therefore, there is a need to address this issue and provide a system that can provide for a more uniform and controlled pressure under the substrate during floatation. With the robust control of the floatation and pressure of the gas under the substrate 110, with controlled and predictable gas escape paths, the entire handling of substrate 110 during the printing process can be more controllable. The present disclosure uses edge control ports disposed on floatation table 105 at locations corresponding to lateral edges of substrate 110 to address the issue discussed above.

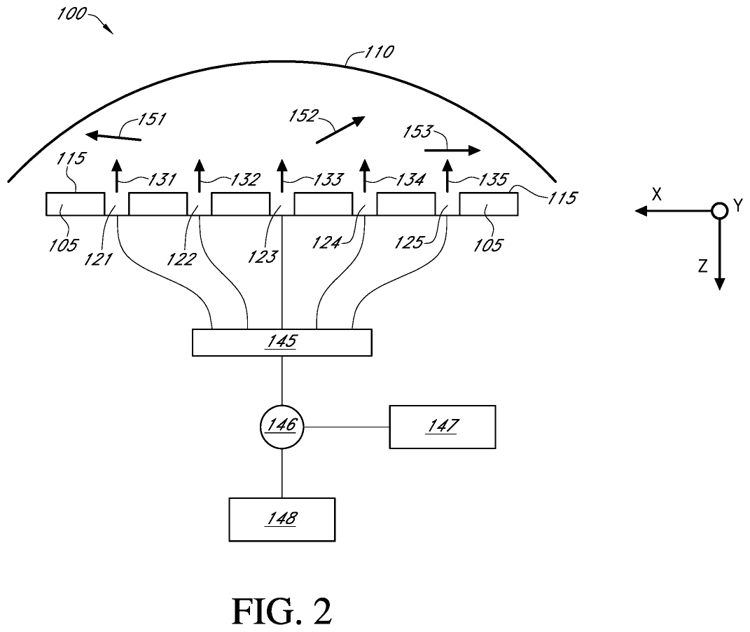

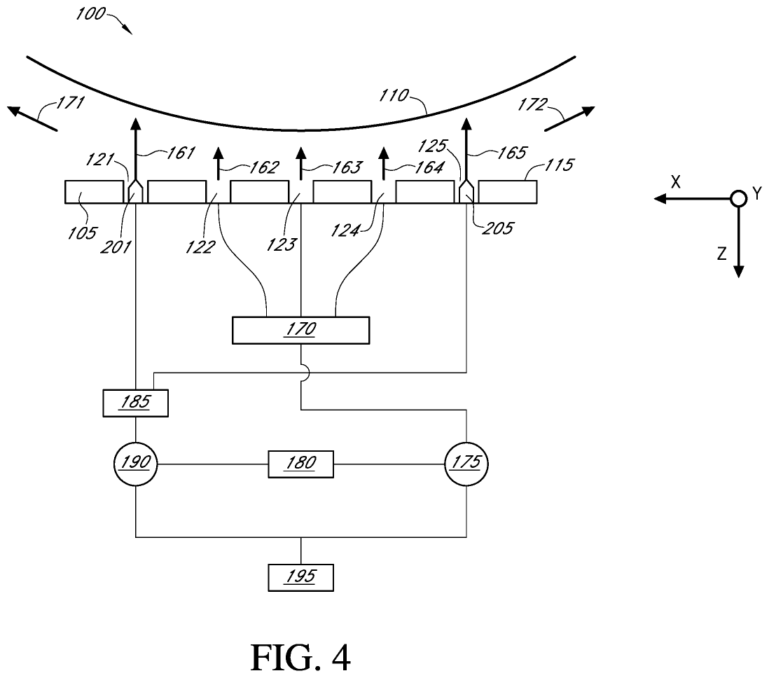

FIG. 2 illustrates a partial side, cross-sectional view of an embodiment of floatation table 105 supporting substrate 110 to schematically depict issues associated with trapped gas. The cross-sectional view is taken across the width of floatation table 105 (i.e., along B-B′ in FIG. 1), which is generally perpendicular to the travel direction A of substrate 110, either at the infeed region 101 or at outfeed region 103. Both infeed region 101 and outfeed region 103 may have pressure ports only for delivering the gas bearing. In other words, floatation table 105 may not include any vacuum ports (also referred to as suction ports) or other escape ports in infeed region 101 and outfeed region 103 for the gas trapped in the central region of the space under substrate 110 to escape. Floatation table 105 may include a plurality of ports 121, 122, 123, 124, and 125, which may be embodiments of ports 120 shown in FIG. 1. For simplicity, to illustrate the issues, ports 121-125 are shown as openings, with no nozzles disposed therein. It is understood that in other embodiments, nozzles may be disposed in these openings, as shown and described further below with reference to FIGS. 4-6.

Ports 121-125 are in flow communication with a gas source 147 through a fluidic network. The fluidic network includes a gas supply manifold 145, a gas control valve 146, and various fluid conduits (also referred to as gas conduits) connecting various components. As illustrated in FIG. 2, each of ports 121-125 is operably coupled (e.g., in flow communication) with gas supply manifold 145. The ports 121-125 can be coupled with the gas supply manifold 145 through gas conduits, such as gas pipes, tubes, etc. Gas may be supplied from gas supply manifold 145 to ports 121-125 at a positive pressure. In some embodiments, the gas supplied to ports 121-125 may be air, nitrogen, another noble or inert gas, or any other suitable gas or combinations thereof. In some embodiments, none of ports 121-125 is used as a vacuum port, for example, when ports 121-125 are located in infeed region 101 or outfeed region 103. In some embodiments, one or more ports 121-125 are used as vacuum ports, for example, when ports 121-125 are located in printing region 102. It is understood that even in infeed region 101 and outfeed region 103, in some embodiments, one or more ports may still be used as vacuum ports.

Gas supply manifold 145 is operably coupled (e.g., in flow communication) with gas control valve 146. Gas control valve 146 can be any suitable power-operated flow control valve, such as a solenoidal valve. In some embodiments, gas control valve 146 is a manually-controlled valve. Gas control valve 146 can be operably coupled with gas source 147. Gas source 147 may be a gas pipe or a gas tank, which may be used to supply a gas to gas control valve 146, gas supply manifold 145, and ports 121-125. In some embodiments, gas source 147 may be a pressurized gas source.

Gas control valve 146 may be operably coupled with a controller 148. Controller 148 can include suitable circuitry, gates, switches, logics, and other suitable software and hardware components. For example, controller 148 may include a processor having circuits and logics for processing signals and providing commands to other devices under control. Controller 148 may be configured or programmed to control gas control valve 146, so as to control the pressure and/or the flow rate of the gas supplied to ports 121-125. Controller 148 may be configured to receive signals from gas control valve 146. Controller 148 can process the signals received from gas control valve 146, and can send signals to gas control valve 146 to regulate the pressure and/or flow rate of the gas supplied to the ports 121-125. Controller 148 may also receive signals from other components included in system 100, such as sensors, actuators, motors. Controller 148 may provide command signals to these components included in system 100 to control the operations thereof.

Although a single gas supply manifold 145 is shown in FIG. 2, system 100 may include more than one gas supply manifold each operably coupled to a group of ports to supply gas separately. The different groups of ports may be supplied with a gas at a same pressure and/or flow rate through the different gas supply manifolds. Alternatively, the different groups of ports may be supplied with a gas at a different pressure and/or a different flow rate through the different gas supply manifolds. When two or more gas supply manifolds 145 are used, there may be two or more gas control valves 146, each controlling the gas supplied to a respective gas supply manifold. In addition, there may be two or more gas sources 147, and two or more controllers 148. Each of the two or more controllers 148 may be configured or programmed to control a respective gas control valve 146, which in turn controls a respective gas supply manifold.

FIG. 2 illustrates gas being supplied from ports 121-125 to the space between surface 115 of the floatation table and substrate 110. Reference numerals 131-135 refer to the flows of the gas supplied from ports 121-125. In some embodiments, the flows 131-135 of the gas have substantially the same pressure and/or flow rate. In some embodiments, the flows 131-135 of the gas have different pressures and/or flow rates. For example, the flows near the central region of the space (e.g., flow 133) may have a pressure and/or flow rate that are smaller than the flows at a non-central region (e.g., flows 131, 132, 134, and 135). As shown in FIG. 2, gas forming the gas bearing can accumulate and be trapped in a generally central region of the space under substrate 110, in this embodiment in the generally central region shown. The accumulation causes a build-up in pressure at the central region, which causes an increase in the fly height at the central region of substrate 110. This in turn causes the substrate 110 to bow in the upward direction such that the surface of substrate 110 facing away from surface 115 of floatation table 105 to have a convex shape, with the fly height at the central region being greater than the fly height at any other regions, such as the lateral edge regions of substrate 110. The illustration of the bowing of the substrate 110 is exaggerated for purposes of illustration and discussion.

The pressure and flow rate of the gas supplied to the central region, non-central region, and edge region may be any suitable values. For example, in some embodiments, the pressure of the gas supplied to the central region, non-central region, and edge region may range from about 4 KPa (kiloPascals) to about 20 KPa, and the flow rate may range from about 200 Liter/minute per square meter of floatation table to about 700 Liter/minute per square meter of floatation table 105.

The gas accumulated at the central region of the space when substrate 110 has a bowed upward shape tends to escape through whichever route or path offers the least resistance. Thus, the escape path becomes random and unpredictable. The routes having the least resistance are arbitrarily indicated by arrow 151 indicating a direction at a first instance, or by arrow 152 indicating another direction at a second instance, or by arrow 153 indicating a further different direction at a third instance while substrate 110 is floatingly supported. The result is that gas escapes from the central region through a random route and in a random X-Y direction. This leads to instability in the fly height at a random portion or region of substrate 110. Reduction of the fly height at a random region of substrate 110, such as at an edge portion in a certain direction, which already has a low fly height, may cause the edge portion to come into contact with another object provided on floatation table 105.

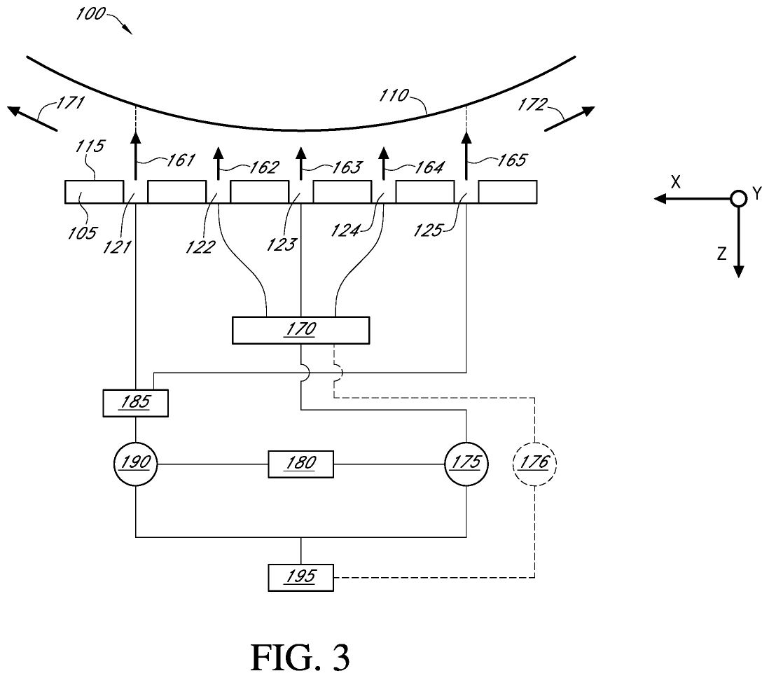

FIG. 3 shows an exemplary embodiment for control over the pressure profiles of a floatation table to address the issues discussed and presented with reference to FIG. 2. FIG. 3 schematically illustrates a partial side, cross-sectional view of an exemplary embodiment of floatation table 105 supporting substrate 110. To address the issues discussed above in connection with FIG. 2, the present disclosure controls gas flows supplied to different regions of substrate 110 through different zones of floatation table 105, to better control pressure under the substrate and thus the overall surface profile and floatation stability of substrate 110. For example, the disclosed system can control gas flows supplied to different regions of substrate 110 through different ports provided in floatation table 105, so as to maintain a substantially uniform pressure under the substrate 110, without significant gas accumulation in regions under the substrate. In some embodiments, the disclosed systems use edge control, i.e., control of the fly heights at the edges of substrate 110 by using edge control ports selectively positioned in floatation table 105. In one embodiment, as shown in FIG. 3, one or more ports located proximate the lateral edges (or peripheral regions) of floatation table 105 in the width direction of substrate 110 may be selected (or configured) for edge control (the width direction being defined as transverse or perpendicular to a direction of conveyance of the substrate 110 along the floatation table 105). Thus, in the embodiment shown in FIG. 3, in which the substrate is in a landscape orientation having a width extending across the entire width of the floatation table) a row of ports along the lateral edge of floatation table 105 on each lateral edge side (e.g., the sides parallel to a direction of travel of the substrate) may be selected for edge control ports. The ports selected for edge control are supplied with a gas at a higher pressure and/or a greater flow rate (to achieve an overall higher unit flow rate) as compared with other ports that are used for providing the gas bearing to float substrate 110. In the embodiment shown in FIG. 3, the ports include openings in floatation table 105. No nozzles are disposed within the openings.

The edge control ports need not to be located at the lateral edges of floatation table 105. For example, when the width of substrate 110 is narrower than the width of floatation table 105 (such as, for example, if a given size substrate is oriented in a portrait orientation in a direction of conveyance), edge control ports may be selected from ports provided in floatation table 105 that are disposed at locations corresponding to the edge regions of substrate 110, which locations may be inward of the ports closest to the lateral edges of the floatation table 105.

In the embodiment shown in FIG. 3, ports 121 and 125 are located near the edges of floatation table 105 in a width direction. This positioning allows ports 121 and 125 to supply flows of gas to edge portions (peripheral portions) of substrate 110 that extend parallel to a direction of travel of the substrate 110, as shown in FIG. 3. Ports 121 and 125 may be arranged for edge controls (hence ports 121 and 125 may be referred to as edge control ports). Ports 122, 123, and 124 may be selected for providing the gas bearing to float substrate 110 (hence ports 122-124 may be referred to as gas bearing ports for ease of description herein). Ports 121-125 are in flow communication with a gas source 180 through a fluidic network. The fluidic network includes a first gas supply manifold 170, a second gas supply manifold 185, a first gas control valve 175, a second gas control valve 190, an optional third gas control valve 176, and various fluid conduits (also referred to as gas conduits) connecting various components. In the exemplary embodiment of FIG. 3, ports 122, 123, and 124 are fluidically coupled with first gas supply manifold 170 through gas conduits (e.g., gas pipes, tubes, etc.), while ports 121 and 125 are be fluidically coupled with second gas supply manifold 185 through gas conduits. First gas supply manifold 170 may be operably coupled with first gas control valve 175 through gas conduits. Second gas supply manifold 185 may be operably coupled with second gas control valve 190 through gas conduits. First and second gas supply manifold 170 and 185 may be similar to gas supply manifold 145 shown in FIG. 2.

Referring to FIG. 3, first and second gas control valves 175 and 190 are operably coupled with gas source 180 through gas conduits. First and second gas control valve 175 and 190 can be similar to gas control valve 146 shown in FIG. 2, and gas source 180 can be similar to gas source 147 shown in FIG. 2. Gas source 180 supplies gas to first and second gas control valves 175 and 190, which in turn supply the gas to first and second gas supply manifolds 170 and 185, respectively. In some embodiments, gas source 180 may be a pressurized gas source. First and second gas control valves 175 and 190 may further be operably coupled with a controller 195 through electronic connections for data and/or signal communication. The electronic connections may be wired or wireless connections. Controller 195 can be similar to controller 148 shown in FIG. 2. Controller 195 can be programmed to control first and second gas control valves 175 and 190 independently to adjust the pressures and/or flow rates of the gas supplied from first and second gas control valves 175 and 190 to first and second gas supply manifolds 170 and 185, respectively.

In an exemplary embodiment, controller 195 is programmed to control first gas control valve 175 such that the gas supplied to first gas supply manifold 170 and ports 122-124 for providing the gas bearing has a first pressure and a first flow rate. Controller 195 is also programmed to control second gas control valve 190 such that the gas supplied to second gas supply manifold 185 and ports 121 and 125 for providing edge controls of the fly height has a second pressure and a second flow rate. Thus, the flow of gas from ports 121 and 125 can differ and be controlled independently from the flow of gas from ports 122-124. For example, in an embodiment, at least one of the second pressure and the second flow rate may be greater than at least one of the first pressure and the first flow rate. Thus, flows 161 and 165 of the gas supplied from ports 121 and 125 at the edges of floatation table 105 have a higher pressure and/or a greater flow rate than flows 162, 163, and 164 of the gas provided from ports 122, 123, and 124.

For example, in one embodiment, the second pressure of the flows 161 and 165 of the gas provided from edge control ports 121 and 125 may be greater than the first pressure of the flows 162, 163, and 164 of the gas provided from ports 122, 123, and 124. Flows 161 and 165 of the gas from ports 121 and 125 may thus be controlled to slightly increase the substrate's fly height near the edge regions of the substrate at which the flows 161 and 165 are directed to prevent accumulation of gas underneath the central region of the substrate. As a result, as depicted in FIG. 3, the fly height across the substrate 110 can be controlled such that the edges of substrate 110 are slightly higher than the fly height at the other regions of substrate, such as the central region of substrate 110, providing the surface of substrate 110 facing away from the floatation table 105 with a substantially flat or slightly concave shape (with FIG. 3 again showing an exaggerated profile for purposes of illustration and discussion). In this way, any gas that accumulates in the space between surface 115 of the floatation table 105 and the lower surface of substrate 110 (i.e., the surface facing the floatation table) can escape the space along fixed or predictable escape routes or paths, as indicated by arrows 171 and 172. As a result, fly height distribution or floatation of substrate 110 becomes more robust, uniform, and easier to control. Moreover, in the fly height profile of substrate 110 shown in FIG. 3, the fly height gradually increases from a region along a centerline of the substrate in the width direction (x-direction) in the figures to a maximum at the outer lateral edges of substrate 110, reduces or eliminates potential contact of substrate 110, particularly the edge portions, with another object on floatation table 105.

In some embodiments, the fly height of the substrate, assuming a flat substrate and floatation table surface, will be generally governed by the following equation:

$$Q = {\int }_{0}^{d} {υ}_{x} dy = \frac{{Gd}^{ 3}}{12 µ} .$$

where Q is gas flow under substrate, d is the fly height, and μ is the viscosity. As reflected in the equation, Q is proportional to the third power of “d.” Thus, a slight change in fly height may significantly increase the amount of the gas flow that may escape the space under substrate, adding instability to the system.

Although a single controller 195 is depicted in FIG. 3 for controlling first and second gas control valves 175 and 190, system 100 may include two or more controllers for independently and separately control first and second gas control valves 175 and 190. System 100 may include other controllers for controlling other components of system 100 that are not shown in FIG. 3. In addition, although a single gas source 180 is shown in FIG. 3 for supplying the gas, system 100 may include two or more separate gas sources to separately supply a first gas and a second gas to first gas control valve 175 and second gas control valve 190, respectively.

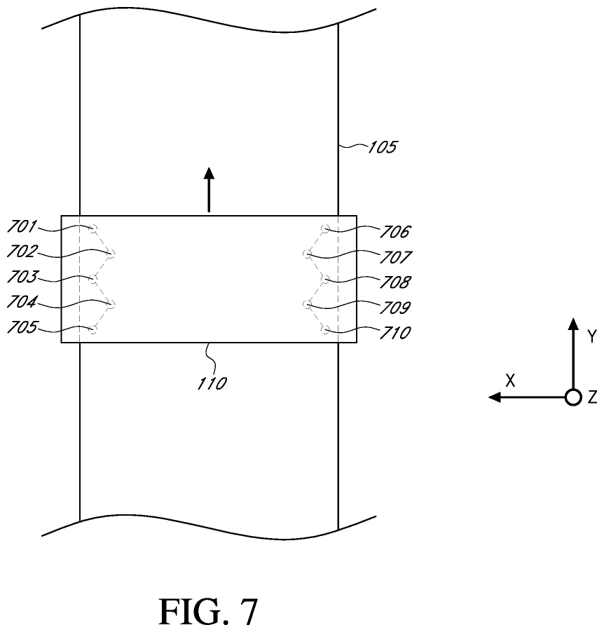

In addition, FIG. 3 shows a cross-sectional view of floatation table 105 with ports 121-125. It is understood that each port represents an array of ports down the length of floatation table 105 (i.e., in the direction into the page of FIG. 3 and along the direction of substrate travel). This arrangement is more clearly depicted in FIGS. 7, 8, and 9 (although only edge control ports are shown). Further, the number of ports shown in the figures extending transverse to the direction of travel is for purposes of illustration and other numbers of ports may be provided, including as part of the group of edge control ports. Moreover, the size, shape, and density of the ports across the table and in different longitudinally extending zones of the floatation tables described herein also may differ and be selected based on a variety of considerations as would be appreciated by those having ordinary skill in the art.

In some embodiments, among the ports for providing the gas bearing, flows of the gas supplied to one or more ports located at the central region may be reduced as compared to flows of the gas supplied to other ports located at non-central regions (e.g., regions between the central region and the edge region where the edge control ports are located). For example, in the embodiment shown in FIG. 3, ports 121 and 125 may be referred to as edge control ports that are located near the edge regions of substrate 110 or floatation table 105. Ports 122 and 124 may be referred to as ports located near non-central regions of substrate 110. Port 123 may be referred to as a port located at a portion on floatation table 105 near a central region of substrate 110. Although in the embodiment of FIG. 3, for simplicity, only one port 123 is shown as located near a central region, and only two ports (122 and 124) are shown in the non-central regions, it is understood that when floatation table 105 includes more ports, the central region may include more than one port, and the non-central regions may include more than two ports.

In the embodiment shown in FIG. 3, flows 162, 163, and 164 are used to provide the gas bearing. Flow 163 supplied through port 123 may be reduced as compared to flows 162 and 164 supplied through ports 122 and 124. For example, at least one of the pressure and the flow rate of flow 163 supplied through port 123 may be reduced as compared to at least one of the corresponding pressure and the corresponding flow rate of flows 162 and 164 supplied through ports 122 and 124. This reduction of flows in the central region may be combined with the supply of the greater flows at the edge control ports (e.g., 121 and 125) to maintain the shape of substrate 110 as substantially flat or slightly concave. Although not repeated in below discussions, the reduction of flows in the central region is also applicable to other embodiments shown in FIGS. 4-9. Accordingly, in various exemplary embodiments 2 or more zones of gas flow ports may be defined in sections of the floatation table that extend parallel to the direction of travel of a substrate along the table (e.g., longitudinally extending sections), and the flow of gas from the ports in the different zones may be independently controlled.

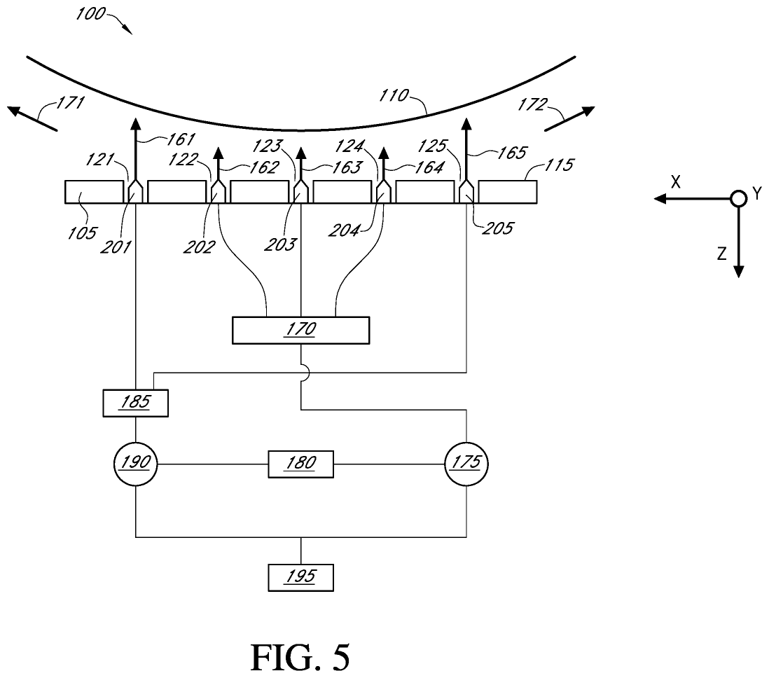

When the flows of gas supplied to the one or more ports located near the central region are reduced, system 100 optionally can include a separate, third gas control valve 176 to control the gas supplied to the one or more ports located near the central region. Third gas control valve 176 may be similar to first and second gas control valves 175 and 190. Third gas control valve 176 may be directly, operably coupled to the one or more ports located near the central region, or may be operably coupled to the one or more ports located near the central region through first gas supply manifold 170. Alternatively, third gas control valve 176 may be operably coupled to the one or more ports located near the central region through a separate gas supply manifold not shown in FIG. 3. In this way, the gas supplied to the one or more ports located near the central region can be independently controlled from the gas supplied to the other ports located in the non-central regions (e.g., regions between the central region and the edge control regions where the edge control ports are located). Third gas control valve 176 may be operably coupled with controller 195 or another controller. Controller 195 may control third gas control valve 176 to reduce the pressure and/or flow rate of the gas supplied to the one or more ports located near the central region as compared to the gas supplied to ports located in the non-central regions. Although not shown in the embodiments of FIGS. 4-5, it is understood that third gas control valve 176 may be optionally included in these embodiments and any other embodiments disclosed herein.

FIG. 4 schematically illustrates a partial side, cross-sectional view of yet another exemplary embodiment of floatation table 105 supporting substrate 110. System components of system 100 shown in FIG. 4 are similar to the system components shown in FIG. 3, except that in the embodiment shown in FIG. 4, additional nozzles 201 and 205 are at least partially disposed within openings 121 and 125 to provide flows of gas for edge controls of the fly heights of substrate 110 at the lateral edge portions of substrate 110. The lateral edge ports of substrate 110 extend parallel to the direction of travel of the substrate 110 through the infeed region 101 and outfeed region 103, and optionally printing region 102. Nozzles 201 and 205 may be any suitable nozzles. In the embodiment shown in FIG. 4, nozzles 201 and 205 are operably coupled with second gas supply manifold 185 through gas conduits. Second gas supply manifold 185 may be operably coupled with second gas control valve 190 through gas conduits. Second gas control valve 190 may be operably coupled with controller 195 through electronic connections.

Controller 195 can be programmed to control first gas control valve 175 to adjust the flow (e.g., the first pressure and/or first flow rate) of the gas supplied to ports 122, 122, and 123. Controller 195 also can control second control valve 190 to adjust the flow (e.g., the second pressure and/or second flow rate) of the gas supplied to nozzles 201 and 205. In an exemplary application, at least one of the second pressure and second flow rate of flows 161 and 165 is greater than at least one of the first pressure and first flow rate of flows 162, 163, and 164 such that the fly height of substrate 110 at the edge portions may be slightly higher than the fly height at the central regions, as shown in FIG. 4 (as discussed above, the surface profile of the substrate shown is exaggerated for the purposes of illustration). The fly height profile or distribution of the fly height of substrate 110 may have a slightly concave shape, similar to the one discussed above in connection with FIG. 3. In other words, substrate 110 can be maintained in a substantially flat or slightly concave shape while being supported and conveyed by floatation table 105. Thus, at least in infeed region 101 and outfeed region 103 wherein floatation table 105 supplies pressurized gas without corresponding precise fly height control through the use of suction ports in combination with pressurized gas ports, the pressure of the gas under the substrate can be controlled to be substantially uniform so as to maintain a generally stable floatation of the substrate without gas being unable to escape in regions under the substrate or leading to unpredictable gas escape paths.

In various exemplary embodiments, nozzles 201 and 205 can deliver pulsed jets of the gas to the edge portions of substrate 110 to provide slight increases to the fly height at the edge regions of the substrate and maintain the desired fly height for substrate 110 so as to provide predictable and desired gas escape routes from the space between the substrate and the floatation table. In some embodiments, nozzles 201 and 205 deliver continuous jets of the gas to the edge portions of substrate 110. In some embodiments, the gas supplied to nozzles 201 and 205, as well as ports 122-124, may be air, nitrogen, another noble gas, an inert gas, or any other suitable gas or combinations thereof.

FIG. 5 schematically illustrates a partial side, cross-sectional view of yet another exemplary embodiment of floatation table 105. The system components shown in FIG. 5 are similar to the system components shown in FIGS. 3 and 4, except that in the embodiment shown in FIG. 5, nozzles 201 and 205 are at least partially disposed within openings 121 and 125 to provide flows of gas for edge control of the fly heights of substrate 110 at the lateral edge portions (parallel to the y-direction of travel of the substrate in the illustration), and nozzles 202, 203, and 204 are at least partially disposed within openings 122, 123, and 124 to provide gas bearing to float substrate 110. In some embodiments, the gas supplied to nozzles 201-205 may be air, nitrogen, a noble gas, an inert gas, or any other suitable gas or combinations thereof. Nozzles 202, 203, and 204 may be similar to nozzles 201 and 205, or may have a different configuration. In the exemplary embodiment of FIG. 5, nozzles 202, 203, and 204 are fluidically coupled with first gas supply manifold 170 through gas conduits. First gas supply manifold 170 is operably coupled with first gas control valve 175 through gas conduits. First gas control valve 175 is operably coupled with controller 195 through electronic connections. Controller 195 is programmed to control first gas control valve 175 to adjust the flow (e.g., at least one of the second pressure and second flow rate) of the gas supplied to first gas supply manifold 170, which is then supplied to nozzles 202, 203, and 204. At least one of the pressure and flow rate of flows 161 and 165 (provided through nozzles 201 and 205) can be controlled to be greater than at least one of the pressure and flow rate of flows 162, 163, and 164 (provided through nozzles 202, 203, and 204). In this way, flows 161 and 165 of gas may slightly raise the fly heights of substrate 110 at the edge regions, such that the fly height profile or distribution has a slightly concave shape. In other words, the pressure of the gas in the space under the substrate 110 can be maintained substantially uniform while the substrate is supported by and conveyed along the floatation table 105, thereby allowing gas to escape predictably and preventing undesirable accumulation under one or more regions of the substrate.

Any suitable nozzle may be used as nozzles 202, 203, 204 for providing the gas bearing. Any suitable nozzle may be used as nozzles 201 and 205 for providing edge control of the fly height of substrate 110 at the lateral edge regions. For example, in one embodiment, the nozzles for providing the gas bearing and/or for edge control can be a SmartNozzle™ commercially available from Coreflow Ltd.

Other floatation tables, such as those utilizing porous materials for providing air bearings as those having ordinary skill in the art are familiar with, may also be used in the disclosed system. To this end, the terms “ports” used herein should be considered to include a variety of openings that can include pores or openings in sintered or ceramic materials from which various floatation tables are made, as well as throughholes or openings formed through a thickness of solid material tables.

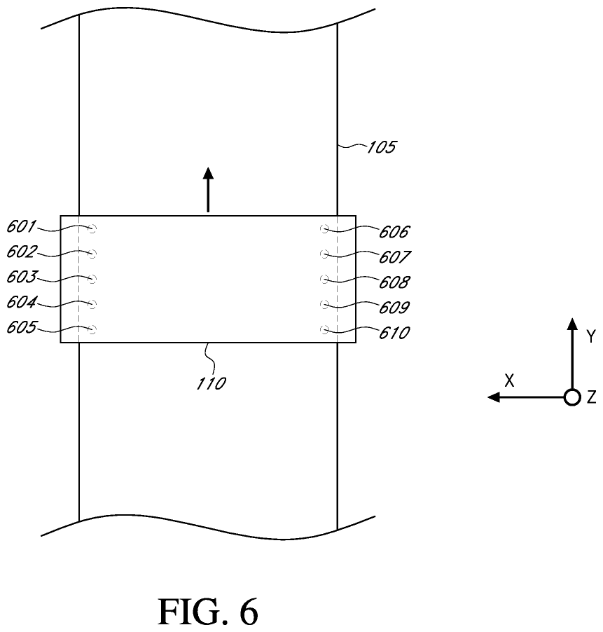

FIG. 6 is a schematic top view of a simplified floatation table 105 with an arrangement of edge control ports at the edges of floatation table 105. FIG. 6 shows floatation table 105 and substrate 110 supported by floatation table 105. For simplicity, only edge control ports (which may be openings or nozzles) provided on floatation table 105 and located in positions that correspond to edge portions of the substrate 110 during the conveyance of substrate 110 along infeed region 101 or outfeed region 103 are shown. Although not shown, similar edge control ports are also distributed along lateral edges of floatation table 105 outside of the area covered by substrate 110 (e.g., the pattern of the shown edge control ports may be repeated along lateral edges outside of the area covered by substrate 110). At the position shown in FIG. 6, substrate 110 may be located in infeed region 101 of floatation table 105, or in outfeed region 103 of floatation table 105. Optionally, at the position shown in FIG. 6, substrate 110 may be located in printing region 102 or other treatment region. In other words, edge control ports shown in FIG. 6 may be located in infeed region 101 or outfeed region 103, or optionally in printing region 102. Other ports provided on floatation table 105 for providing the gas bearing are not shown for simplicity of illustration. For example, ports similar to those shown in FIGS. 1, 3, 4, and 5 for providing gas bearing are generally distributed over the entire surface of floatation table 105.

As shown in FIG. 6, in this embodiment, a column of edge control ports may be located on each lateral edge side (including areas that are not covered by substrate 110) to provide edge control of the fly height of substrate 110. At the location of substrate 110 in FIG. 6 during conveyance of substrate 110 in one of the infeed region 101 or outfeed region 103 (or optionally printing region 102), substrate 110 may be supported by edge control ports 601-605 on the left side and by edge control ports 606-610 on the right side for providing edge control. For simplicity, other ports provided on floatation table 105 for providing gas bearing in the area covered by substrate 110 are not shown, however those having ordinary skill in the art would appreciate that ports similar to those shown in FIGS. 1, 3, 4, and 5 for providing gas bearing are generally distributed over the entire surface of floatation table 105. In some embodiments, the gas supplied to edge control ports 601-610 may be air, nitrogen, another noble gas, an inert gas, or any other suitable gas or combinations thereof.

In the disclosed embodiments, such as embodiment shown in FIG. 6, substrate 110 is depicted as being wider than floatation table 105, with edge portions 111 and 112 of substrate 110 overhanging from the lateral edges of floatation table 105. In some embodiments, substrate 110 may be narrower than floatation table 105. Thus, no edge portions of substrate 105 may overhang from the edges of floatation table 105. In such arrangements, certain ports provided in floatation table 105 that are positioned near the edge portions of substrate 105 may be selected as edge control ports. The flow of gas in different longitudinally extending sections, i.e., sections extending in a direction parallel to the direction of substrate travel along the floatation table, of the floatation table may thus be controlled so as to provide substantial pressure uniformity in the space under the substrate. For example, gas with a higher pressure and/or flow rate may be supplied through these selected ports to raise the fly height of substrate 110 at the edge portions, thereby creating a concave shape for the fly height profile, with the central portions of substrate 110 having the lowest fly height. In other words, any ports provided in floatation table 105 may be selected as edge control ports. Such ports need not be located at the edges of floatation table 105. For example, such ports may be located at anywhere, as long as they can provide gas flows to edge portions of the substrate. Gas with a higher pressure and/or flow rate may be supplied to such ports to alter the fly height at the edge portions of substrate 110 as needed to provide predictable escape paths for the gas from the space between the floatation table and the substrate.

FIG. 7 is a schematic top view of a simplified floatation table 105 with another arrangement of edge control ports at the edges of floatation table 105. FIG. 7 shows floatation table 105 and substrate 110 supported by floatation table 105. Similar to the embodiment shown in FIG. 6, for simplicity, FIG. 7 only shows the edge control ports (which may be openings or nozzles) provided on floatation table 105 and located at positions corresponding to edge portions of substrate 110 and covered by substrate 110 during the conveyance of substrate 110 along infeed region 101 or outfeed region 103 (or optionally at printing region 102). As shown in FIG. 7, on each lateral edge side, edge control ports 701-705 may be offset from one another (rather than in a straight column). If the edge control ports 701-705 are connected by lines, the lines may show a zig-zag pattern, as shown in FIG. 7. Similarly, edge control ports 706-710 on the right lateral edge side may also be offset from one another to form a zig-zag pattern.

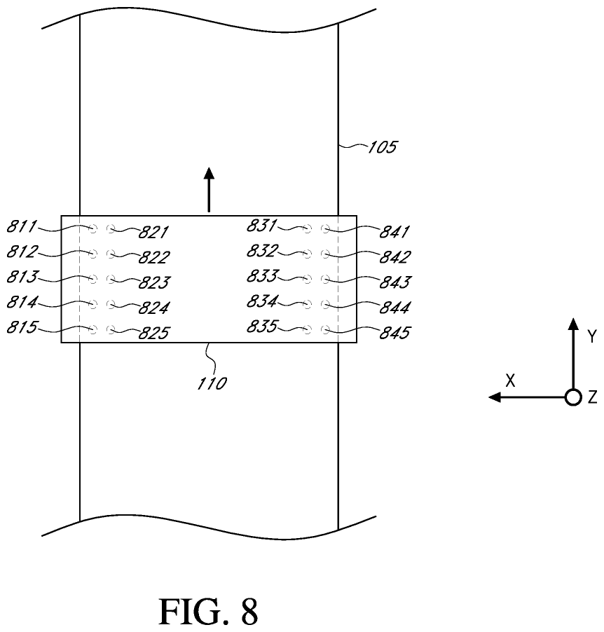

FIG. 8 is a schematic top view of a simplified floatation table 105 with another arrangement of edge control ports at the edges of floatation table 105. FIG. 8 shows floatation table 105 and substrate 110 supported by floatation table 105. Similar to FIGS. 6 and 7, for simplicity, FIG. 8 only shows edge control ports (which may be openings or nozzles) provided on floatation table 105 and located in the edge areas covered by substrate 110 at a location of the substrate 110 during the conveyance of substrate 110 along infeed region 101 or outfeed region 103. As shown in FIG. 8, on each lateral edge side, two columns of edge control ports may be used for edge controls. For example, on the left lateral edge side of floatation table 105, edge control ports 811-815 and 821-825 may be distributed for edge control. On the right lateral edge side, edge control ports 831-835 and 841-845 may be distributed for edge control. Although two columns are shown on each edge side in the embodiments in FIG. 8, it is understood that more than two columns of edge control ports may be used on each edge side for edge controls.

It should be understood by those having ordinary skill in the art that when porous or sintered material floatation tables are used, the gas supplied to zones of the table (such as edge zones) with their in situ pores (“ports”) may be controlled rather than control of flow through individual openings in the floatation table.

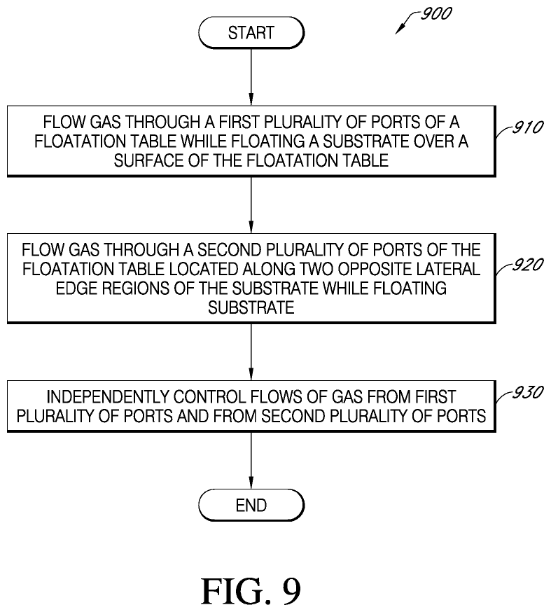

FIG. 9 is a flowchart illustrating exemplary steps of a method for supporting a substrate in accordance with the present disclosure. Method 900 may be performed by system 100 disclosed herein. For example, method 900 may be performed by any controller disclosed in the various embodiments of system 100, such as controller 195, and in combination with other components included in system 100, such as the gas supply manifolds, the gas control valves, any pressure and/or flow rate sensors that may be included in system 100, which may not have been shown in the previous figures.

Method 900 may include flowing gas at a first flow rate and a first pressure through a first plurality of ports of a floatation table to establish a gas bearing sufficient to float a substrate over a surface of the floatation table (step 910). For example, in the embodiment shown in FIGS. 3 and 4, ports 122-124 may supply flows of the first gas to provide a gas bearing between surface 115 and substrate 110 to float substrate 110 over surface 115. The first gas may have a first flow rate and a first pressure. Controller 195 may control first gas control valve 175 to adjust the pressure and/or flow rate of the gas supplied to first gas supply manifold 170, thereby adjusting the pressure and/or flow rate of the gas supplied from ports 122-124 for floating substrate 110. The pressure and/or flow rate may be adjusted by controller 195, such that sufficient force is provided by the gas bearing generated by the flows of gas to float substrate 110 over surface 115 of floatation table 105. The fly height of substrate 110 may be in a range of about 30 microns to 500 microns, for example on the order of a few hundred microns for different portions of substrate 110, such as from 100 microns near the central regions to about 250 microns or more near the edge regions.

In the embodiment shown in FIG. 3, among the ports for providing the gas bearing, controller 195 may control the gas supplied to ports located at the central region independently from other ports located at the non-central regions, such that the flows (e.g., pressure and/or flow rate of flows) supplied from the ports located at the central region are smaller than the flows supplied from the ports located at the non-central regions. The reduction in the flows supplied from the ports located at the central region may help alleviate the pressure build-up at the central region, thereby helping maintain the concave shape of the surface of substrate 110 that faces away from floatation table 105 when edge controls are also implemented, as discussed above. For example, controller 195 may control the gas supplied to ports located at the central region independently through an optional third gas control valve 176 and an optional, separate gas supply manifold (not shown in FIG. 3) (or through first gas supply manifold 170).

In the embodiment shown in FIG. 5, controller 195 may control first gas control valve 175 to adjust the pressure and/or flow rate of the gas supplied to first gas supply manifold 170, which in turn supplies the gas to ports 202-204 (in forms of nozzles 202-204) provided in floatation table 105. As discussed above, although not shown in FIGS. 4-5, the embodiments shown in FIGS. 4-5 may also include the optional third gas control valve 176 for separately, independently controlling the ports located at the central region. Thus, the above discussions of separately and independently reducing the flows at the central region are also applicable to the embodiment of FIG. 5.

Method 900 may also include flowing gas at a second flow rate and a second pressure through a second plurality of ports of the floatation table and toward the substrate. The second plurality of ports may be located along two opposite edge sections of the floatation table that extend parallel to the direction of travel of the substrate along the table, each section being on an opposite side of the section containing the first plurality of o ports, wherein at least one of the second flow rate and the second pressure is greater than at least one of the first flow rate and the first pressure (step 920). For example, in the embodiments shown in FIGS. 3-5, edge control ports 121 and 125 may supply flows of a second gas (which may be the same or different from the first gas for providing the gas bearing) to two edge regions of the substrate 110 that extend parallel to the conveyance direction of substrate 110. At step 930 in FIG. 9, the flow of the first gas to the first plurality of ports and the flow of the second gas to the second plurality of ports can be independently controlled to prevent undesirable gas accumulation leading to floatation instability. For example, the flows may be independently controlled such that a substantially uniform pressure occurs in the space under the substrate. In an exemplary embodiment, as has been discussed, one or more of the second pressure and/or flow rate of the gas flowing from the edge control ports may be higher than that from the first ports. With reference again to the exemplary embodiment of FIGS. 3-5, controller 195 may control second gas control valve 190 to adjust the pressure and/or flow rate of the gas supplied through ports 121 and 125. The pressure and/or flow rate of the gas may be adjusted such that the pressure and/or flow rate are greater than the pressure and/or flow rate of the flows of gas supplied through ports 122-124 for providing the gas bearing.

Controller 195 may adjust the pressure and/or flow rate of the flows of gas supplied through ports 121 and 125, such that fly height at the edge portion of substrate 110 is controlled, which may be such that the edge portions are slightly higher in fly height than the fly height at the central region of substrate 110. Thus, gas supplied for providing the gas bearing can escape the space between substrate 110 and surface 115 of floatation table 105 in relatively constant direction or flow path. As a result, the gas would not escape the space in a random, unpredictable path, thereby reducing or eliminating the chance for the edges of substrate 110 to hit other objects on floatation table 105, leading to a more stable and uniform overall fly height distribution of the substrate and surface profile of the substrate.

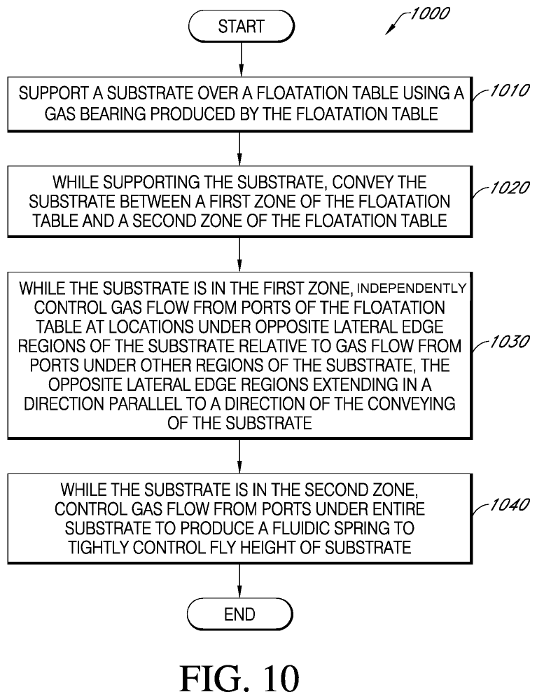

FIG. 10 is a flowchart illustrating exemplary steps of another method for supporting a substrate in accordance with the present disclosure. Method 1000 may be performed by system 100 disclosed herein. For example, method 1000 may be performed by any controller disclosed in the various embodiments of system 100, such as controller 195, and in combination with other components included in system 100, such as the gas supply manifolds, the gas control valves, any pressure and/or flow rate sensors that may be included in system 100, which may not have been shown in the previous figures.

Method 1000 may include supporting a substrate over a floatation table using a gas bearing produced by the floatation table (step 1010). For example, floatation table 105 may supply flows of gas to a space between surface 115 and substrate 110 to create a gas bearing to support substrate 110 over surface 115. Method 100 may also include while supporting the substrate, conveying the substrate between a first region of the floatation table and a second region of the floatation table (step 1020). For example, while substrate 110 is supported using the gas bearing, floatation table 110 (or another component of system 100) may convey substrate 110 between a first region (e.g., infeed region 101 or outfeed region 103) and a second region (e.g., printing region 102 or other treatment region). Method 1000 may also include while the substrate is in the first region, controlling a gas flow from the floatation table at locations under opposite lateral edge regions of the substrate, the opposite lateral edge regions extending in a direction parallel to a direction of the conveying of the substrate (step 1030). For example, while substrate 110 is located in infeed region 101 or outfeed region 103, any controller disclosed herein may control a gas flow from floatation table 110 at locations under opposite lateral edge regions of substrate 110 independently of the flow of gas supplied from other ports to other regions of substrate 110, as discussed above in connection with FIGS. 3-8. The opposite edge regions may be on opposite lateral sides of the substrate 110 and extend in a direction parallel to a direction of the conveying of substrate 110. The flows of gas from the ports under the edge regions of the substrate can be controlled independently of flows of gas from ports under other regions of the substrate so as to achieve a substantially uniform pressure of gas in the space under the substrate in order to provide predictable gas escape paths and avoid trapping of gas leading to instability in floatation and potential collision/damage of the substrate.

Method 1000 may further include while the substrate is in the second region, controlling a gas flow from the floatation table to produce a substantially uniform fly height over an entirety of the substrate (step 1040) through the use of a fluidic spring. For example, while substrate 110 is in printing region 102, any a controller similar to those disclosed in FIGS. 3-5, or any of the controller disclosed in FIGS. 3-5, may control a gas flow from floatation table 105 to produce a substantially uniform and tightly controlled fly height over an entirety of substrate 110. For example, in some embodiments, the controller may control the gas flows such that some ports in floatation table 105 are supplied with a pressurized gas, some ports in floatation table 105 are subject to a vacuum force that withdraws the gas from the space between substrate 110 and surface 115. Both the pressure and the vacuum may increase the effective stiffness of the fluidic spring generated by both the pressurized gas and the vacuum. More uniform and tight fly height control may be achieved with the increased effective stiffness. In some embodiments, overhanging edge portions 111 and 112 may counter the weight of the central portions of substrate 110, thereby help creating a more uniform fly height distribution across substrate 110.

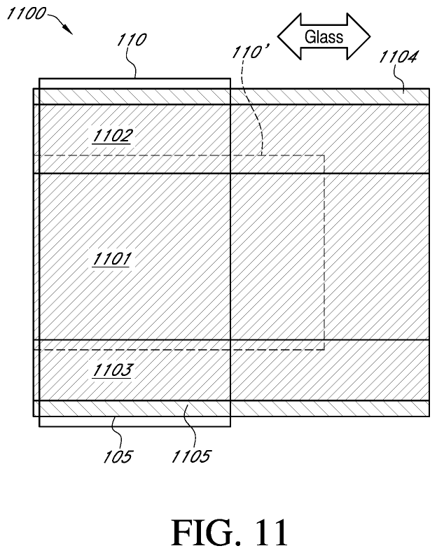

FIG. 11 schematically depicts how a floatation table in accordance with various exemplary embodiments can accommodate substrates having different orientations (or widths) while still providing edge control ports and corresponding gas flows to achieve the desirable pressure uniformity and stable floatation in accordance with the present disclosure. Floatation table 105 includes a plurality of zones extending generally parallel to a direction of conveyance of a substrate (110 or 110′). As shown, floatation table 105 comprises a central zone 1101, edge zone 1104 and 1105, and non-central zones 1102 and 1103 located between the central zone 1101 and the edge zones 1104, 1105. Each zone comprises a plurality of ports (not shown for ease of illustration) which can be arranged in arrays or other configurations as has been described with respect to other exemplary embodiments herein. The gas flow to ports in the edge zones, the ports in the central zone, and the ports in the non-central zones can be independently controlled to achieve desirable pressure uniformity and floatation stability of a substrate as it is conveyed along the floatation table 105. By providing the three or more different zones of ports with independent gas flow control, including at least the edge zones 1104, 1105 with a first plurality of ports, the noncentral zones 1102, 1103 with a second plurality of ports, and the central zone 1101 with a third plurality of ports, and independent control of flow over those zones, the floatation table can achieve desirable substrate floatation control for various formats and orientations of substrates.

The regions making up the noncentral zones 1102, 1103 and/or those making up the edge zones 1104, 1105 need not be of equal size. For example, the zoning may be skewed to match the location on the substrate, for example, if the substrate is not placed symmetrically at the center of the table. Further, edge zones 1104, 1105 may be operated if the placement of a substrate, such as substrate 110′, having a narrower width than the width of the floatation table is skewed (e.g., laterally to either side of center) as it is conveyed. In some applications, for example, one lateral side of the substrate may be aligned over one of the edge zones 1104, 1105, but due to the overall width of the substrate its opposite edge may only lie over one of the noncentral zones and not extend fully to the opposite edge zone.

For example, as can be seen in FIG. 11, when a substrate is oriented such that a width of the substrate (dimension perpendicular to substrate conveyance along the table 105) extends across all of the zones 1101-1105, the ports in zones 1104 and 1105 can be controlled as edge control ports, as has been described above, with a unit flow rate of gas higher from those ports than from ports in zones 1101, 1102, and 1103. Zones 1102 and 1103 can be controlled to have substantially the same flow as ports in 1101, or may be controlled to have an unit flow rate between that of the central zone 1101 and the edge zones 1104, 1105. In another exemplary use scenario, when a substrate is oriented or has dimensions such that its width is smaller than the floatation table such that the substrate does not extend over ports of the edge zones 1104, 1105 (as illustrated by substrate 110′ in FIG. 11), flow control in the various zones (i.e., central zone 1101, noncentral zones 1102, 1103, and edge zones 1104, 1105) can be controlled such that gas flowing through the ports in zones 1102 and 1103 are controlled as edge control ports as they are under the edge regions of the substrate 110′, and the gas flow through the ports in the central zone 1101 can be controlled as has been described for other embodiments above. The ports in the edge zones 1104, 1105, which are not positioned under the substrate 111′ can be turned off completely in an exemplary embodiment so as to produce no gas flow. Thus, providing at least three independently controllable zones of gas flow ports provides for flexibility in selecting which zones of ports will be controlled as edge control ports to achieve desirable gas flows directed to different regions of the substrate in accordance with the present disclosure.

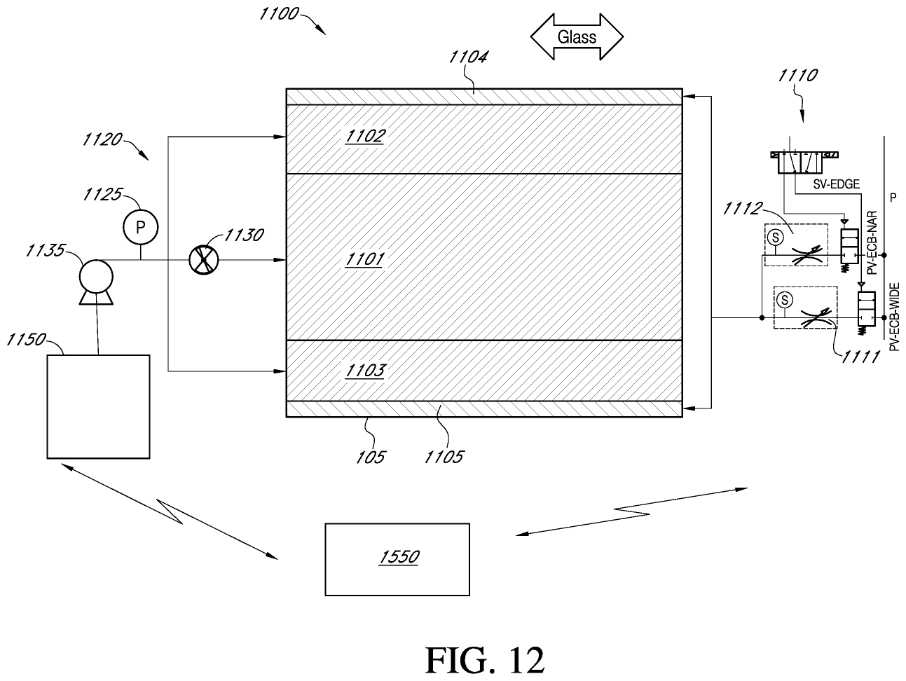

FIG. 12 schematically illustrates one exemplary embodiment of a pneumatic system 1100 that includes fluidic components and controls for supplying and independently controlling the gas flow to the ports of the different zones (i.e., zones 1104, 1105, zones 1102, 1103, and zone 1101) of floatation table 105. As shown in FIG. 12, pneumatic system 1100 includes a first gas supply subsystem 1110 and a second gas supply subsystem 1120. With reference to FIG. 12, an exemplary embodiment of a pneumatic system is shown. A first gas supply subsystem 1110 supplies the gas to ports of edge zones 1104 and 1105, and a second gas supply subsystem 1120 supplies the gas to ports of the central zone 1101 and non-central regions 1102 and 1103. Pneumatic system 1100 also includes a controller 1550 for controlling the various components included in system 1100. Controller 1550 may be any suitable controller known in the art, and may be programmed or coded based on the methods and processes disclosed herein.

First gas supply subsystem 1110 includes a high pressure regulator or controller 1111 and a low pressure regulator or controller 1112. Each of the high pressure regulator 1111 and low pressure regulator 1112 may control the pressure of the flows, and may include any suitable components with which those of ordinary skill in the art are familiar. A suitable pressure may be achieved for the gas supplied to the edge zones 1104 and 1105 by controlling the low pressure regulator 1112, high pressure regulator 1111, or a combination thereof.

Second gas supply subsystem 1120 includes a pressure sensor 1125, a valve 1130 and a blower 1135. Pressure sensor 1125 may be any suitable pressure sensor that may measure a pressure of a gas in a gas conduit. Valve 1130 may be any suitable valve for controlling fluid flow, such as a gas flow control valve. In some embodiments, valve 1130 may be a ball valve. Blower 1135 may be any suitable blower for blowing gas. Blower 1135 may include various components, such as a motor and a variable frequency controller 1150 that controls the speed of the motor. In an exemplary embodiment, blower 1135 may be a centrifugal pump. As shown in FIG. 12, second gas supply subsystem 1120 supplies gas to the non-central zones 1102 and 1103, as well as the zone 1101. In an exemplary embodiment, the gas supplied to central zone 1101 is controlled by ball valve 1130, whereas the gas supplied to non-central zones 1102 and 1103 is not controlled ball valve 1130. As described above, the gas flow supplied to the central zone 1101 may be reduced as compared to the non-central zones 1102 and 1103 so as to alleviate the pressure build-up in the space under the central region 1101 of substrate 110. The reduction of the gas flow supplied to the central zone 1101 may be performed by adjusting the ball valve 1130.

When a substrate such as 110′ that has a width that does not extend to the edge zones 1104, 1105 is supported by the floatation table, the first gas supply subsystem can be shut off from supplying gas to the zones 1104, 1105, for example through a valve or from a fluid supply source. The second gas supply subsystem can be controlled to provide a higher flow of gas (unit flow rate through a higher pressure and/or flow rate) through the ports of noncentral zones 1102, 1103, which become edge control ports as they are positioned under the edge regions of the substrate 110′, as compared to the ports of the central zone 1101 that are positioned under the central region of the substrate 110′.

In some embodiments, pneumatic system 1100 may include a controller 1550 in communication with first gas supply subsystem 1110 and second gas supply subsystem 1120. Controller 1550 may control various components of first gas supply subsystem 1110 and second gas supply subsystem 1120 to adjust the pressure and/or flow rate of the gas supplied to the different zones (1101, 1102/1103, and 1104/1105) for supporting substrate 110 and/or for pressure distribution of gas in the space under substrate 110, 110′.

In some embodiments, a pneumatic system in accordance with the present disclosure may include various sensors for measuring the fly heights at various portions of substrate. For example, one or more laser sensors, such as a laser triangulation sensor, for measuring the fly heights at various portions of substrate 110 can be utilized. In addition, one or more sensors can be used to determine an orientation or dimensions of the substrate relative to the floatation table.

Controller 1150 can receive signals from the one or more sensors and other components of first gas supply subsystem 1110 and second gas supply subsystem 1120 and control the gas supply through the first gas supply subsystem 1110 and second gas supply subsystem 1120 based on the signals received. For example, if excessive bowing of the substrate at a central region is measured, controller 1150 can be used to determine the width of the substrate and to adjust gas flows in ports in zones corresponding to edge regions of the substrate so as to provide desired and predictable gas path escape routes to maintain a stability and uniformity of the fly height and surface profile of the substrate. Controller 1150 can use any suitable control schemes, such as, but not limited to for example, a feedback control, a feedforward control, a proportional control, a robust control, etc. Controller 1150 may be similar to other controllers disclosed herein, or may be an embodiment of other controllers disclosed herein.

The pneumatic system 1100 of FIG. 12 is exemplary and nonlimiting of the present disclosure, and those having ordinary skill in the art would appreciate a variety of other fluidics components and control systems to provide the selective and independent control over different zones of ports to achieve the uniformity in pressure of floatation gas in a space under a substrate, and in a manner such that a variety of substrate sizes and orientations can be accommodated.

While various exemplary embodiments are described as the substrate being in a slightly concave configuration with respect to the surface of the substrate facing away from the table, it should be appreciated that in general it is desirable to maintain a substantially flat surface profile of the substrate with only slight deviations of concavity or convexity being tolerated. The figures showing concave surface profiles of the substrate are exaggerated for illustration and to help depict that the gas flow rate and/or pressures at edge regions may be relatively high compared to those in more central regions in accordance with various aspects of the present disclosure. Further, those of ordinary skill in the art would appreciate that the number of zones of gas flow may be selected based on the desired control and surface profiles of the substrate in different regions of the substrate as desired.

Various exemplary embodiments of the present disclosure discuss the use of gas flow through the floatation table. It should be understood that a variety of gases may be used and the gasses in each zone can be the same or different. Moreover, each zone of ports may have the same or different sizes, layouts, and density of ports without departing from the scope of the present disclosure. It is further contemplated that fluids other than gases may be used in the floatation tables. For example, in some applications, it may be desirable to flow liquid from the ports of a floatation table.

The exemplary systems and methods described herein may be performed under the control of a processor or controller executing computer-readable codes embodied on a computer-readable recording medium or communication signals transmitted through a transitory medium. The computer-readable recording medium may be any data storage device that may store data readable by a processor or controller, and may include both volatile and nonvolatile media, removable and non-removable media, and various other network devices.

Examples of the computer-readable recording medium include, but are not limited to, read-only memory (ROM), random-access memory (RAM), erasable electrically programmable ROM (EEPROM), flash memory or other memory technology, holographic media or other optical disc storage, magnetic storage including magnetic tape and magnetic disk, and solid-state storage devices. The computer-readable recording medium may also be distributed over network-coupled computer systems so that the computer-readable code is stored and executed in a distributed fashion. The communication signals transmitted through a transitory medium may include, for example, modulated signals transmitted through wired or wireless transmission paths.

Devices manufactured using embodiments of the devices, systems, and methods of the present disclosure may include, for example and without limitation, electronic displays or display components, printed circuit boards, or other electronic components. Such components may be used in, for example, handheld electronic devices, televisions or computer displays, or other electronic devices incorporating display technologies.

It will be understood that the present disclosure is not limited to the systems set forth in the appended claims and that other systems, devices, and methods are contemplated and considered within the scope of the disclosure. For instance, the present disclosure further contemplates a method comprising flowing gas from a plurality of ports of a floatation table to establish a gas bearing under a surface of a substrate, the gas bearing being sufficient to float a substrate the floatation table as the substrate is conveyed along the floatation table; and independently controlling flows of gas through ports of the plurality of ports disposed in each of a first zone, a second zone, and a third zone of the floatation table. The first, second, and third zones may be defined by sections of the floatation table extending parallel to a direction the substrate is conveyed along the floatation table, with the first zone defined by a central section of the floatation table disposed between two sections defining the second zone, and the first and second zones disposed between two sections defining the third zone.

Independently controlling the flows of gas may include selectively flowing or stopping the flow of gas while floating the substrate. The method may further be implemented such that a density of ports in at least two of the first, second, and third zones differ. Independently controlling the flows of gas may include independently controlling the flows of gas in each zone based on width of the substrate, where the width of the substrate is measured in a direction perpendicular to the direction of conveyance of the substrate along the floatation table. The method may further include sensing a fly height of the substrate at different locations of the substrate, and independently controlling the flows of gas may include independently controlling the flows of gas in each zone based in response to sensing a predetermined deviation of fly height at one or more locations of the substrate. Independently controlling the flows of gas may include independently controlling the flows of gas to achieve a substantially uniform pressure of gas against the surface of the substrate while it is being floated. Independently controlling the flows of gas may include flow gas from the ports of the first and second zones substantially uniformly. A gas supplied to the ports of each of the first, second, and third zones is a same type of gas chosen from air or an inert gas. Independently controlling flows of gas through the ports of each of the first, second and third zones may include independently controlling at least one of pressure and flow rate of gas through the ports of each of the first, second, and third zones.

The present disclosure further contemplates a method comprising flowing gas from a plurality of ports of a floatation table to establish a gas bearing under a surface of a substrate, the gas bearing being sufficient to float a substrate the floatation table as the substrate is conveyed along the floatation table. Flowing the gas may comprise flowing a first gas at a first flow rate and a first pressure through a first plurality of ports of a floatation table, and flowing a second gas at a second flow rate and a second pressure through a second plurality of ports of the floatation table, wherein the second plurality of ports are located under two opposite lateral edge regions of the substrate, the first plurality of ports are located under a region of the substrate between the two opposite lateral edge regions, and at least one of the second flow rate and the second pressure is greater than at least one of the first flow rate and the first pressure.

Implementations of the method may be such that the two opposite lateral edge regions extend in a direction parallel to a direction the substrate is conveyed along the floatation table during processing of the substrate to manufacture an electronic display device. Flowing the first gas through the first plurality of ports may include flowing the first gas through a first plurality of nozzles in the floatation table. Flowing the second gas through the second plurality of ports may include flowing the second gas through a second plurality of nozzles in the floatation table. In an implementation, the floatation table has an infeed region, a printing region, and an outfeed region disposed in series along a direction the substrate is conveyed along the floatation table, and flowing the first gas through the first plurality of ports and flowing the second gas through the second plurality of ports occur in at least one of the infeed region and the outfeed region. The method may further comprise flowing the second gas through the second plurality of ports causes gas trapped under a region of the substrate to escape at the lateral edges of the substrate. Flowing the first gas through the first plurality and the second gas through the second plurality of ports may include flowing an inert gas through the first plurality and second plurality of ports. The first gas and the second gas may be the same gas or different gases.

The present disclosure further contemplates a method of processing a substrate that may comprise supporting the substrate over a floatation table using a gas bearing produced by the floatation table; while supporting the substrate, conveying the substrate between a first region of the floatation table and a second region of the floatation table; while the substrate is in the first region, controlling gas flow in differing zones of the floatation table so as to allow gas to escape in a substantially uniform manner from under the substrate; and while the substrate is in the second zone, controlling a gas flow from the floatation table to produce a fluidic spring to control a fly height of the substrate.

The method may further include controlling the gas flow by adjusting a flow of gas from zones of the floatation table under opposite lateral edge regions of the substrate differently than a flow of gas from a zone of the floatation table under a central region of the substrate, where the opposite lateral edge regions of the substrate extend parallel to a direction the substrate is conveyed between the first region and the second region of the floatation table. The method may include depositing a material from an inkjet printing assembly while the substrate is in the second region. The method may also include loading the substrate to the first region prior to supporting the substrate using the gas bearing. The method may include unloading the substrate with the material deposited thereon from the first region. Depositing the material may include depositing an organic light-emissive material. Controlling the gas flow while the substrate is in the second region may include using a combination of pressurized gas flows and suction gas flows from the floatation table. In an implementation, gas used in the floatation table is an inert gas, such as, for example chosen from nitrogen, a noble gas, or any combination thereof.

The methods disclosed herein may further include depositing a material on the substrate, such as, for example, via inkjet printing of the material on the substrate. The material may be an organic material, such as, for example, a material used to form a layer of an organic light emitting diode display.

It is to be understood that the examples and embodiments set forth herein are non-limiting, and modifications to structure, dimensions, materials, and methodologies may be made without departing from the scope of the present teachings. Other embodiments in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

1. A system, comprising:
a floatation table comprising a plurality of ports to flow gas to float a substrate over the floatation table and enable transport of the substrate in a conveyance direction, the floatation table having a first region, a second region, and a third region distributed in the conveyance direction, with the third region between the first region and the second region;
a fluidic network to supply gas to the plurality of ports of the floatation table; and
a controller configured to control the fluidic network to independently control flows of gas through ports of the plurality of ports in the first region located in each of a central zone and
an edge zone, the edge zone corresponding to an edge of the substrate and the central zone corresponding to a central area of the substrate.

2. The system of claim 1, further comprising a printhead assembly mounted over the third region of the floatation table.

3. The system of claim 2, wherein the edge zone is a first edge zone, and the controller is further configured to control the fluidic network to independently control flows of gas through ports of the plurality of ports in the first region located in a second edge zone corresponding to an edge of the substrate, wherein the central zone is between the first edge zone and the second edge zone.

4. A system, comprising:
a floatation table comprising a plurality of ports to flow gas to float a substrate over the floatation table and enable transport of the substrate in a conveyance direction, the floatation table having a first region, a second region, and a third region distributed in the conveyance direction, with the third region between the first region and the second region;
a printhead assembly mounted over the third region of the floatation table;
a fluidic network to supply gas to the plurality of ports of the floatation table; and
a controller operably coupled to the fluidic network, the controller configured to:
independently control flows of gas through ports of the plurality of ports in the first region located in each of a central zone, a first edge zone and a second edge zone, the first and second edge zones corresponding to opposite edges of the substrate and the central zone corresponding to a central area of the substrate and located between the first and second edge zones.

5. (canceled)

6. The system of claim 4, wherein the fluidic network comprises:
a first gas supply manifold fluidly coupled with the ports of the central zone;
a first gas control valve operably coupled with the first gas supply manifold;
a second gas supply manifold fluidly coupled with the ports of the first and second edge zones; and
a second gas control valve operably coupled with the second gas supply manifold,
wherein the controller is operably coupled with the first gas control valve and the second gas control valve to adjust at least one of a pressure or flow rate of the gas to the ports of the central zone and the first and second edge zones.

7-15. (canceled)

16. The system of claim 3, further comprising a gas source and a vacuum source fluidly coupled to the plurality of ports via the fluidic network, wherein the controller is further configured to control the fluidic network to apply vacuum from the vacuum source to a portion of the ports of the third region.

17. The system of claim 3, wherein the controller is further configured to control the fluidic network to independently control flows of gas through ports of the plurality of ports in the first region located in a non-central zone between the first edge zone and the second edge zone.

18. The system of claim 17, wherein the non-central zone is a first non-central zone, and the controller is further configured to control the fluidic network to independently control flows of gas through ports of the plurality of ports in the first region located hi a second non-central zone between the first edge zone and the second edge zone, and the central zone is between the first and second non-central zones.

19. The system of claim 18, further comprising a gas source and a vacuum source fluidly coupled to the plurality of ports via the fluidic network, wherein the controller is further configured to control the fluidic network to apply vacuum from the vacuum source to a central portion of the ports of the third region.

20. The system of claim 4, further comprising a gas source and a vacuum source fluidly coupled to the plurality of ports via the fluidic network, wherein the controller is further configured to control the fluidic network to apply vacuum from the vacuum source to a first portion of the ports located in a central area of the third region and pressure to a second portion of the ports distributed across the third region.

21. The system of claim 4, wherein the controller is further configured to control the fluidic network to independently control flows of gas through ports of the plurality of ports in the second region located in each of a central zone, a first edge zone and a second edge zone, the first and second edge zones corresponding to opposite edges of the substrate and the central zone corresponding to a central area of the substrate and located between the first and second edge zones.

22. The system of claim 4, wherein the controller is further configured to control the fluidic network to independently control flows of gas through ports of the plurality of ports in the first region located in a non-central zone between the first edge zone and the second edge zone.

23. The system of claim 22, wherein the non-central zone is a first non-central zone, and the controller is further configured to control the fluidic network to independently control flows of gas through ports of the plurality of ports in the first region located hi a second non-central zone between the first edge zone and the second edge zone, and the central zone is between the first and second non-central zones.

24. A system, comprising:
a floatation table comprising a plurality of ports to flow gas sufficient to produce a gas bearing to float a substrate over the floatation table and enable transport of the substrate in a conveyance direction, the floatation table having a first region, a second region, and a third region distributed in the conveyance direction, with the third region between the first region and the second region;
a printhead assembly mounted over the third region of the floatation table;
a fluidic network coupled to supply gas to the plurality of ports of the floatation table; and
a controller configured to control the fluidic network to independently control flows of gas through ports of the plurality of ports in:
the first region located in each of a central zone, a non-central zone, a first edge zone and a second edge zone, the first and second edge zones corresponding to opposite edges of the substrate, the central zone corresponding to a central area of the substrate and located between the first and second edge zones, and the non-central zone boated between the first and second edge zones; and
the second region located in each of a central zone, a non-central zone, a first edge zone and a second edge zone, the first and second edge zones corresponding to opposite edges of the substrate, the central zone corresponding to a central area of the substrate and located between the first and second edge zones, and the non-central zone located between the first and second edge zones.

25. The system of claim 24, further comprising a gas source and a vacuum source fluidly coupled to the plurality of ports via the fluidic network, wherein the controller is further configured to control the fluidic network to apply vacuum from the vacuum source to a first portion of the ports located in a central area of the third region and pressure to a second portion of the ports distributed across the third region.
